(19) United States
(12) Patent Application Publication
(10) Pub. No.: US 2016/0099418 A1
(43) Pub. Date: Apr. 7, 2016

(54) ORGANIC ELECTROLUMINESCENT DEVICE

(71) Applicant: SAMSUNG DISPLAY CO., LTD., Yongin-si (KR)

(72) Inventors: Hiromi Nakano, Yokohama (JP); Shuri Sato, Yokohama (JP)

(21) Appl. No.: 14/839,688

(22) Filed: Aug. 28, 2015

(30) Foreign Application Priority Data
Oct. 6, 2014 (JP) 2014-205459

(51) Int. Cl. H01L 51/00

(52) U.S. Cl. CPC H01L 51/0061; H01L 51/0072; H01L 51/006; H01L 51/0052; H01L 51/0073; H01L 51/0067; H01L 51/0074; H01L 51/0058; H01L 51/0094; H01L 51/5206

(57) ABSTRACT

An organic electroluminescent device includes an anode, an emission layer, a first hole transport layer between the anode and the emission layer, the first hole transport layer including a first hole transport material and an electron accepting material doped into the first hole transport material, and a second hole transport layer between the anode and the emission layer, the second hole transport layer including a second hole transport material represented by Formula 2:

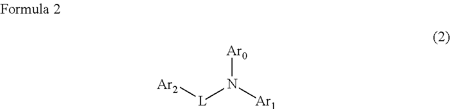

### CROSS-REFERENCE TO RELATED APPLICATIONS

This U.S. non-provisional patent application claims priority to and the benefit of Japanese Patent Application No. 2014-205459, filed on Oct. 6, 2014, the entire content of which is incorporated herein by reference.

### BACKGROUND

1. Field

One or more aspects of embodiments of the present disclosure relate to an organic electroluminescent device.

2. Description of the Related Art

Recently, the development of an organic electroluminescent display is being actively conducted. In addition, the development of a self-luminescent organic electroluminescent device capable of being used in the organic electroluminescent display is also being actively conducted.

An organic electroluminescent device may include, for example, an anode, a hole transport layer on the anode, an emission layer on the hole transport layer, an electron transport layer on the emission layer, and a cathode on the electron transport layer.

In an organic electroluminescent device, holes and electrons injected from the anode and the cathode recombine in the emission layer to generate excitons, and light may be emitted when the excitons transition from an excited state to a ground state.

### SUMMARY

However, emission efficiency and emission life of previously prepared organic electroluminescent devices are not satisfactory, and thus the emission efficiency and emission life may be improved.

One or more aspects of embodiments of the present disclosure provide a novel and improved organic electroluminescent device capable of improving at least one of emission efficiency and emission life.

One or more embodiments of the present disclosure provide an organic electroluminescent device including an anode, an emission layer, a first hole transport layer between the anode and the emission layer, the first hole transport layer including a first hole transport material and an electron accepting material doped into the first hole transport material, and a second hole transport layer between the anode and the emission layer, the second hole transport layer including a second hole transport material represented by Formula 2:

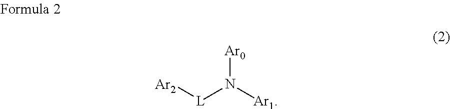

In the above Formula 2, Ar₀ and Ar₁ are each independently selected from a substituted or unsubstituted aryl group and a substituted or unsubstituted heteroaryl group, and at least one selected from Ar₀ and Ar₁ is substituted with a substituted or unsubstituted silyl group; Ar₂ is a substituted or unsubstituted dibenzofuranyl group; and L is selected from a direct linkage, a substituted or unsubstituted arylene group, and a substituted or unsubstituted heteroarylene group.

According to one or more embodiments of the present disclosure, at least one of the emission efficiency and emission life of the organic electroluminescent device may be improved.

In some embodiments, the substituted silyl group may be substituted with a substituted or unsubstituted aryl group.

According to one or more embodiments of the present disclosure, at least one of the emission efficiency and emission life of the organic electroluminescent device may be improved.

In some embodiments, the substituted silyl group may be substituted with an unsubstituted phenyl group.

According to one or more embodiments of the present disclosure, at least one of the emission efficiency and emission life of the organic electroluminescent device may be improved.

In some embodiments, L may be coupled with Ar₂ at position three (3) of the dibenzofuranyl group.

According to one or more embodiments of the present disclosure, at least one of the emission efficiency and emission life of the organic electroluminescent device may be improved.

In some embodiments, the first hole transport material may be represented by Formula 1:

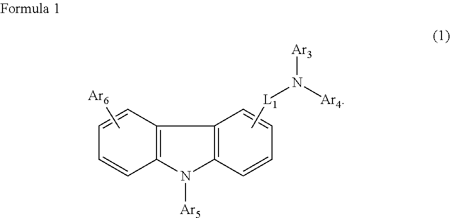

In Formula 1, Ar₃ to Ar₅ are each independently selected from a substituted or unsubstituted aryl group and a substituted or unsubstituted heteroaryl group; Ar₆ is selected from a substituted or unsubstituted aryl group, a substituted or unsubstituted heteroaryl group, a carbazolyl group, and an alkyl group; and L₁ is selected from a direct linkage, a substituted or unsubstituted arylene group, and a substituted or unsubstituted heteroarylene group.

According to one or more embodiments of the present disclosure, at least one of the emission efficiency and emission life of the organic electroluminescent device may be improved.

In some embodiments, the electron accepting material may have the lowest unoccupied molecular orbital (LUMO) level from about −9.0 eV to about −4.0 eV.

According to one or more embodiments of the present disclosure, at least one of the emission efficiency and emission life of the organic electroluminescent device may be improved.

In some embodiments, the emission layer may include a luminescent material represented by Formula 3:

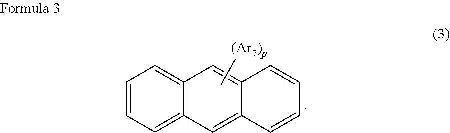

In Formula 3, Ar₇ is selected from a hydrogen atom, a deuterium atom, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group and a hydroxyl group; and p is an integer from 1 to 10.

According to one or more embodiments of the present disclosure, at least one of the emission efficiency and emission life of the organic electroluminescent device may be improved.

In some embodiments, the second hole transport layer may be between the first hole transport layer and the emission layer.

According to one or more embodiments of the present disclosure, at least one of the emission efficiency and emission life of the organic electroluminescent device may be improved.

In some embodiments, the second hole transport layer may be adjacent to the emission layer.

According to one or more embodiments of the present disclosure, at least one of the emission efficiency and emission life of the organic electroluminescent device may be improved.

In some embodiments, the first hole transport layer may be adjacent to the anode.

According to one or more embodiments of the present disclosure, at least one of the emission efficiency and emission life of the organic electroluminescent device may be improved.

In some embodiments, a third hole transport layer may be further provided between the first hole transport layer and the second hole transport layer and may include at least one selected from the first hole transport material and the second hole transport material.

According to one or more embodiments of the present disclosure, at least one of the emission efficiency and emission life of the organic electroluminescent device may be improved.

As described above, according to one or more embodiments of the present disclosure, the first hole transport layer and the second hole transport layer may be provided between the anode and the emission layer, and at least one of the emission efficiency and emission life of the organic electroluminescent device may be increased.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1 is a cross-sectional view illustrating the schematic configuration of an organic electroluminescent device according to one or more embodiments of the present disclosure; and

FIG. 2 is a cross-sectional view illustrating a modification of an organic electroluminescent device according to one or more embodiment of the present disclosure.

### DETAILED DESCRIPTION

Example embodiments of the present disclosure will be described below in more detail with reference to the accompanying drawings. In the specification and drawings, elements having substantially the same function will be designated by the same reference numeral, and repeated explanation thereof will not be provided. In addition, the expression “a compound represented by Formula A (where A is a numeral)” may also refer to “Compound A”.

### Configuration of Organic Electroluminescent Device

### 1-1. Substantially Whole Configuration

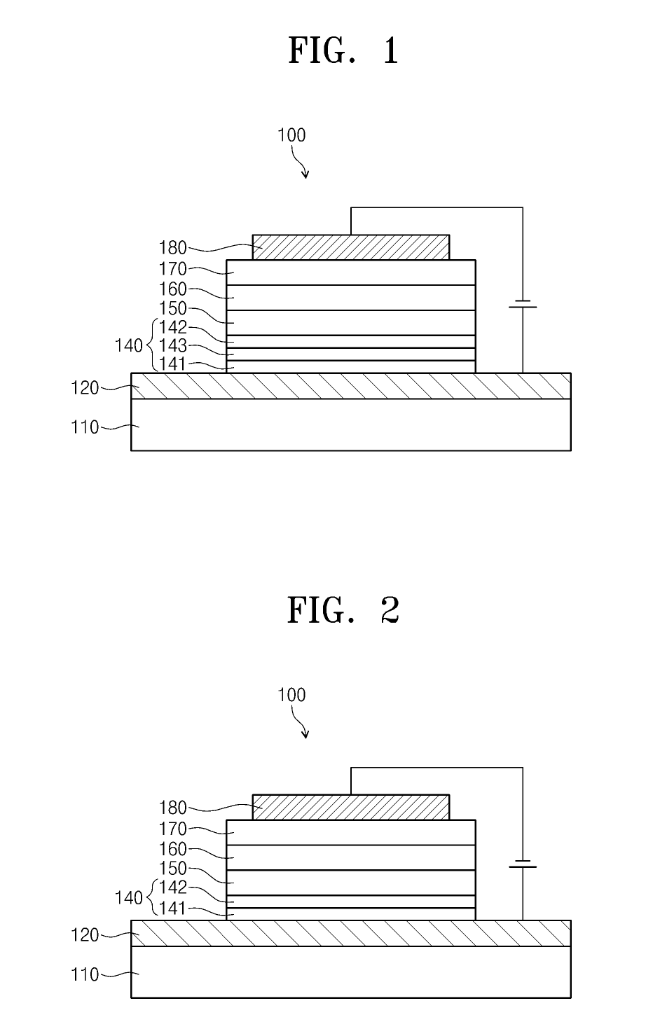

First, referring to FIG. 1, the whole (or substantially whole) configuration of an organic electroluminescent device 100 according to one or more embodiments of the present disclosure will be explained. As shown in FIG. 1, the organic electroluminescent device 100 according to an embodiment may include a substrate 110, a first electrode 120 on the substrate 110, a hole transport layer 140 on the first electrode 120, an emission layer 150 on the hole transport layer 140, an electron transport layer 160 on the emission layer 150, an electron injection layer 170 on the electron transport layer 160, and a second electrode 180 on the electron injection layer 170. The hole transport layer 140 may be formed to have a multi-layered structure composed of a plurality of layers 141, 142, and 143.

### 1-2. Configuration of Substrate

The substrate 110 may be any suitable substrate generally available in the art of organic electroluminescent devices. For example, the substrate 110 may be a glass substrate, a semiconductor substrate, or a transparent plastic substrate.

### 1-3. Configuration of First Electrode

The first electrode 120 may be, for example, an anode, and may be formed on the substrate 110 using an evaporation method, a sputtering method, and/or the like. For example, the first electrode 120 may be formed as a transmission type electrode using a metal, an alloy, a conductive compound, and/or the like, having large work function. The first electrode 120 may be formed using, for example, indium tin oxide (ITO), indium zinc oxide (IZO), tin oxide (SnO₂), zinc oxide (ZnO), and/or the like, having good transparency and conductivity. In some embodiments, the first electrode 120 may be formed as a reflection type electrode using magnesium (Mg), aluminum (Al), and/or the like.

### 1-4. Configuration of Hole Transport Layer

The hole transport layer 140 may include a hole transport material having hole transporting function. The hole transport layer 140 may be formed, for example, on the hole injection layer to a layer thickness (total layer thickness of a stacked structure of the hole transport layer 140) of about 10 nm to about 150 nm. In some embodiments, the hole transport layer 140 may include a first hole transport layer 141, a second hole transport layer 142, and a third hole transport layer 143. The thickness ratio of the layers is not specifically limited.

### 1-4-1. Configuration of First Hole Transport Layer

In some embodiments, the first hole transport layer 141 is a layer adjacent to (e.g., directly contacting) the first electrode 120. The first hole transport layer 141 may include a first hole transport material and an electron accepting material doped into the first hole transport material.

The first hole transport material may be represented by the following Formula 1. According to one or more embodiments of the present disclosure, the properties of the organic electroluminescent device 100 may be improved by using the compound represented by the following Formula 1 as the first hole transport material:

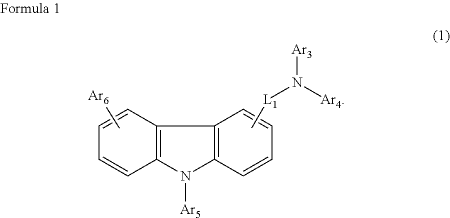

In the above Formula 1, Ar₃ to Ar₅ may each independently be selected from a substituted or unsubstituted aryl group or a substituted or unsubstituted heteroaryl group. Non-limiting examples of Ar₃ to Ar₅ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a benzoxazolyl group, a benzothiazolyl group, a quinoxalyl group, a benzoimidazolyl group, a pyrazolyl group, a dibenzofuranyl group, a dibenzothienyl group, and the like. In some embodiments, Ar₃ to Ar₅ may each independently be selected from the phenyl group, the biphenyl group, the terphenyl group, the fluorenyl group, the dibenzofuranyl group, and the like.

Ar₆ may be selected from a substituted or unsubstituted aryl group, a substituted or unsubstituted heteroaryl group, a carbazolyl group, and an alkyl group. Non-limiting examples of the aryl group and the heteroaryl group are the same as those provided in connection with Ar₃ to Ar₅. In some embodiments, the aryl group and the heteroaryl group may each independently include a phenyl group, a biphenyl group, a terphenyl group, a fluorenyl group, a dibenzofuranyl group, and/or a carbazolyl group.

L₁ may be selected from a direct linkage (e.g., a bond, such as a single bond), a substituted or unsubstituted arylene group, and a substituted or unsubstituted heteroarylene group.

Non-limiting examples of L₁ may include a phenylene group, a biphenylene group, a terphenylene group, a naphthalene group, an anthrylene group, a phenanthrylene group, a fluorenylene group, an indenylene group, a pyrenylene group, an acetonaphthenylene group, a fluoranthenylene group, a triphenylenylene group, a pyridylene group, a furanylene group, a pyranylene group, a thienylene group, a quinolylene group, an isoquinolylene group, a benzofuranylene group, a benzothienylene group, an indolylene group, a carbazolylene group, a benzoxazolylene group, a benzothiazolylene group, a kinokisariren group, a benzoimidazolylene group, a pyrazolylene group, a dibenzofuranylene group, a dibenzothienylene group, and the like. In some embodiments, L₁ may include the phenylene group, the biphenylene group, the terphenylene group, the fluorenylene group, the carbazolylene group, the dibenzofuranylene group, and/or the like.

The first hole transport material represented by the above Formula 1 may include at least one compound represented by any of the following Formulae 1-1 to 1-16:

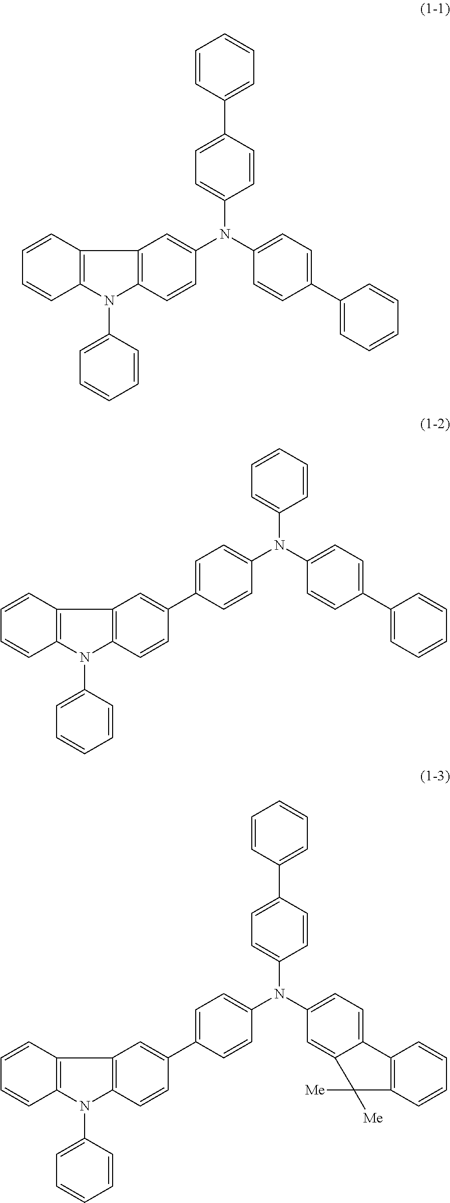 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

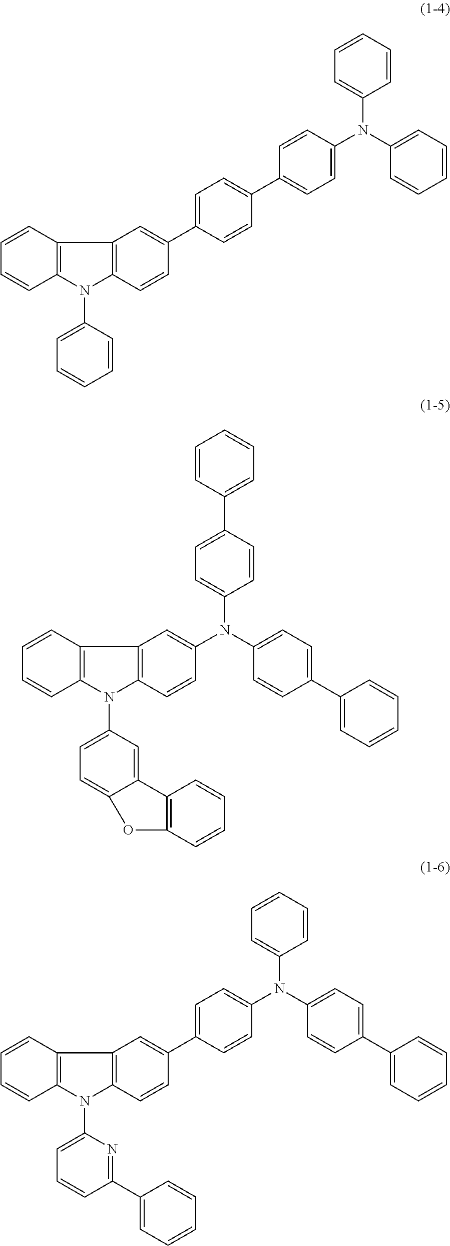 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

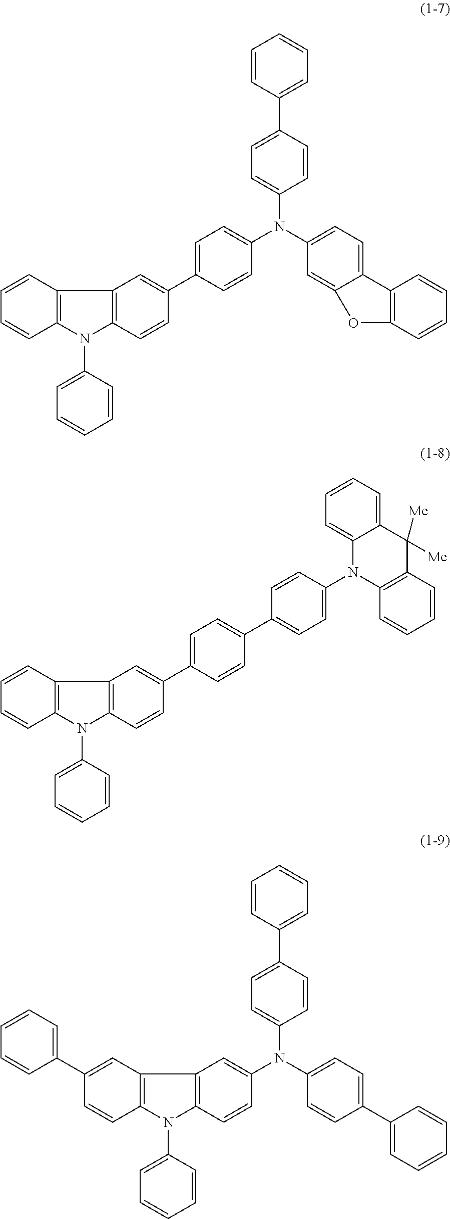 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

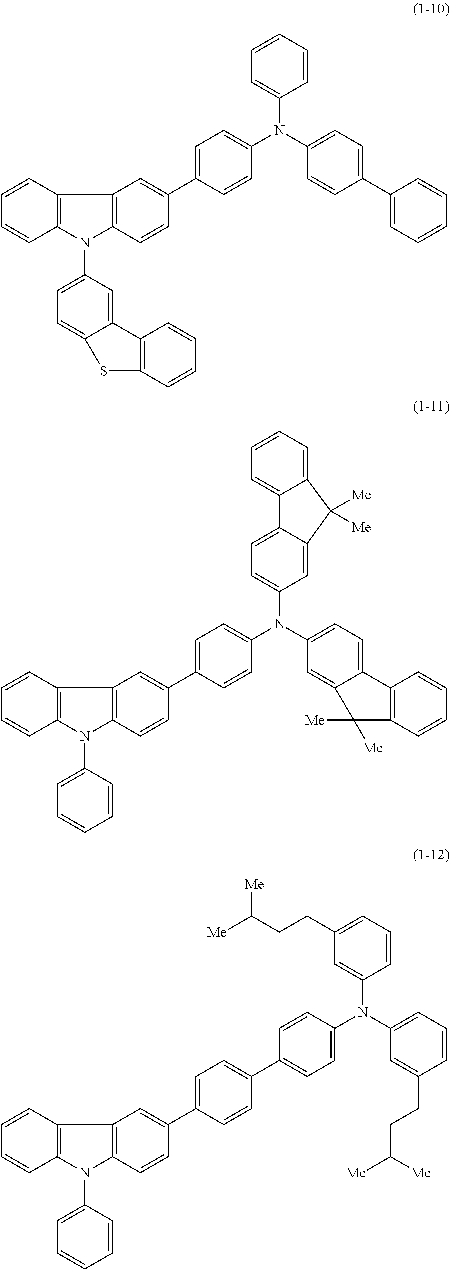 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

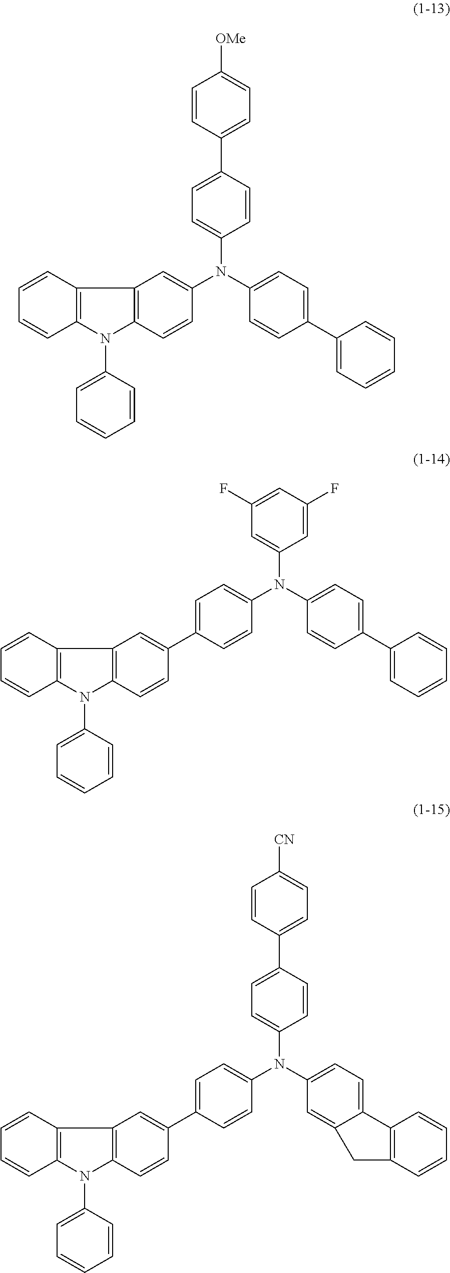 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

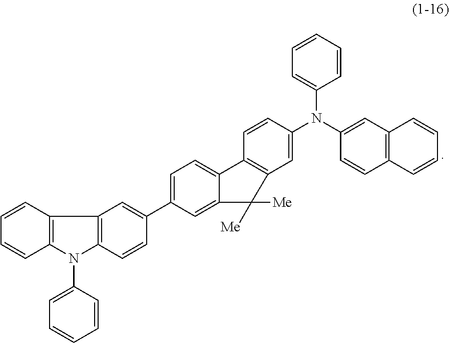 [SMILES: CC1(C)c2cc(-c3ccc4c(c3)c3ccccc3n4-c3ccccc3)ccc2-c2ccc(N(c3ccccc3)c3ccc4ccccc4c3)cc21]

In Formulae 1-1 to 1-16, the symbol “Me” refers to a methyl group.

In some embodiments, the first hole transport material may be any suitable hole transport material other than the above-mentioned materials. Non-limiting examples of the first hole transport material may include 1,1-bis[(di-4-tolylamino)phenyl]cyclohexane (herein, TAPC), a carbazole derivative (such as N-phenyl carbazole, polyvinyl carbazole, and/or the like), N,N′-bis(3-methylphenyl)-N,N′-diphenyl-[1,1-biphenyl]-4,4′-diamine (herein, TPD), 4,4′,4″-tris(N-carbazolyl)triphenylamine (herein, TCTA), N,N′-di(1-naphthyl)-N,N′-diphenylbenzidine (NPB), and/or the like. For example, the first hole transport material may be any suitable hole transport material generally available in the art of organic electroluminescent devices. In some embodiments, the first hole transport material may be represented by Formula 1.

The electron accepting material may be any suitable electron accepting material generally available in the art of organic electroluminescent devices. In some embodiments, the electron accepting material may have a lowest unoccupied molecular orbital (LUMO) level from about −9.0 eV to about −4.0 eV, for example, from about −6.0 eV to about −4.0 eV. Non-limiting examples of the electron accepting material having the LUMO level from about −9.0 eV to about −4.0 eV may include compounds represented by the following Formulae 4-1 to 4-14:

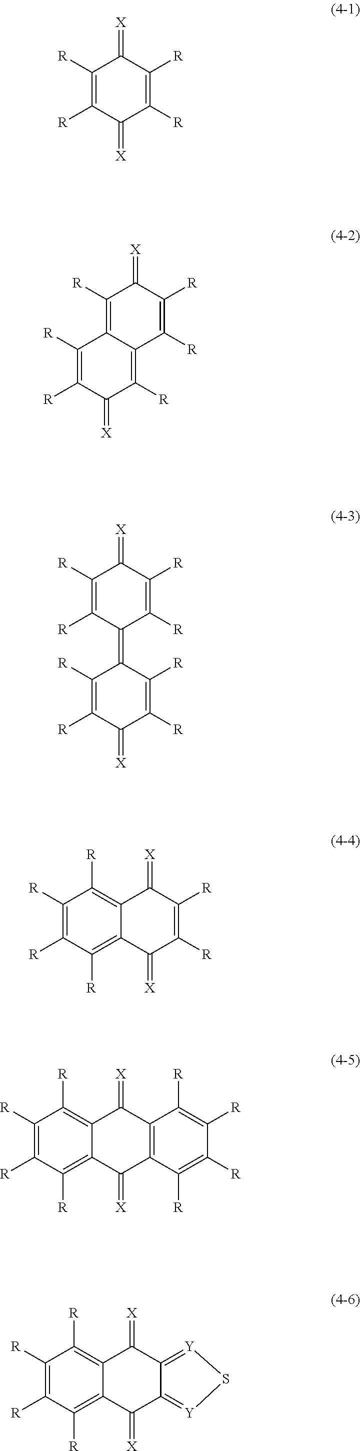

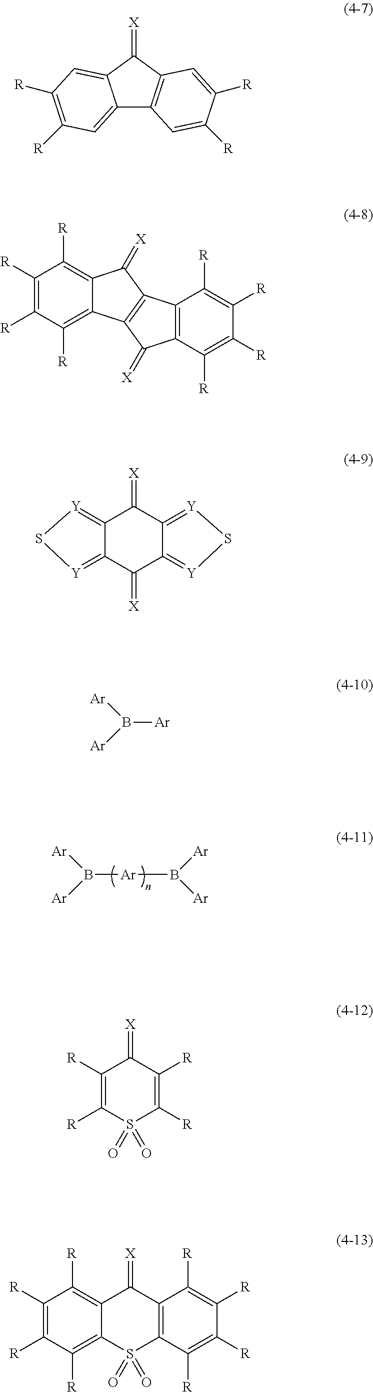

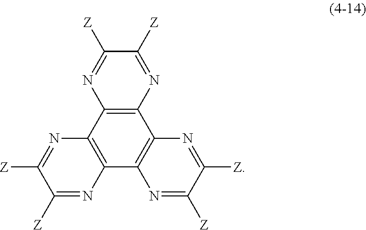

In the above Formulae 4-1 to 4-14, R may be selected from a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, an aryl group having 6 to 50 carbon atoms for forming a ring, and a heteroaryl group having 5 to 50 carbon atoms for forming a ring. As used herein, the statement “atoms for forming a ring” may refer to “ring-forming atoms.” Ar may be selected from a substituted aryl group with an electron withdrawing group, an unsubstituted aryl group having 6 to 50 carbon atoms, and a substituted or unsubstituted heteroaryl group having 5 to 50 carbon atoms for forming a ring. Y may be a methine group (—CH═) or a nitrogen atom (—N═); Z may be a pseudohalogen (e.g., a pseudohalogen group) or may include sulfur (S) (e.g., Z may be a sulfur-containing group); n may be an integer of 10 or less; and X may be selected from the substituents represented by the following Formulae X1 to X7:

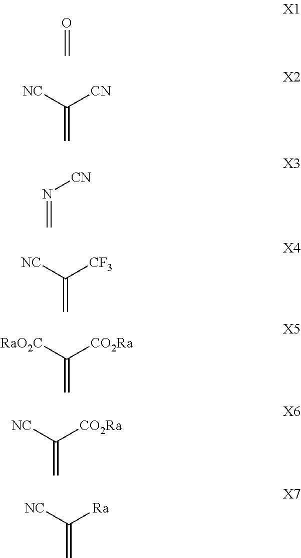

In the above Formulae X1 to X7, Ra may be selected from a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 6 to 50 carbon atoms for forming a ring, and a substituted or unsubstituted heteroaryl group having 5 50 carbon atoms for forming a ring.

Non-limiting examples of the substituted or unsubstituted aryl group having 6 50 carbon atoms for forming a ring and the substituted or unsubstituted heteroaryl group having 5 to 50 carbon atoms for forming a ring represented by R, Ar and/or Ra may include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-tolyl group, a m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, a 4″-t-butyl-p-terphenyl-4-yl group, a fluoranthenyl group, a fluorenyl group, a 1-pyrrolyl group, a 2-pyrrolyl group, a 3-pyrrolyl group, a pyrazinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,9-phenanthroline-6-yl group, a 1,8-phenanthroline-7-yl group, a 1,8-phenanthroline-9-yl group, a 1,9-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrole-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrole-4-yl group, a 3-methylpyrrole-5-yl group, a 2-t-butylpyrrole-4-yl group, a 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl-3-indolyl group, and the like.

Non-limiting examples of the substituted or unsubstituted fluoroalkyl group having 1 to 50 carbon atoms represented by R and/or Ra may include a perfluoroalkyl group such as a trifluoromethyl group, a pentafluoroethyl group, a heptafluoropropyl group and a heptadecafluorooctane group, a monofluoromethyl group, a difluoromethyl group, a trifluoroethyl group, a tetrafluoropropyl group, an octafluoropentyl group, and the like.

Non-limiting examples of the substituted or unsubstituted alkyl group having 1 to 50 carbon atoms represented by R and/or Ra may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, and the like.

The substituted or unsubstituted alkoxy group having 1 to 50 carbon atoms represented by R and/or Ra may be a group represented by —OY. Non-limiting examples of Y may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, and the like. Non-limiting examples of the halogen atom represented by R and/or Ra may include fluorine, chlorine, bromine, iodine, and the like.

Non-limiting examples of the electron accepting material may include the following Compounds 4-15 and 4-16. For example, the LUMO level of Compound 4-15 may be about −4.40 eV, and the LUMO level of Compound 4-16 may be about −5.20 eV.

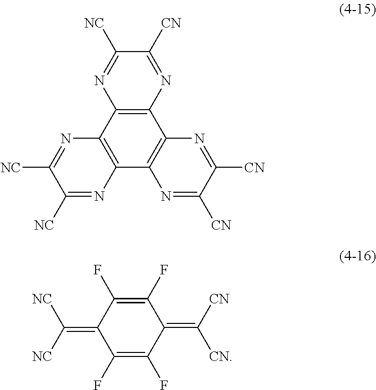 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

The doping amount of the electron accepting material may be any suitable amount capable of being doped as (or into) the hole transport material, without specific limitation. In some embodiments, the doping amount of the electron accepting material may be from about 0.1 wt % to about 50 wt % based on the total amount of the first hole transport material constituting the first hole transport layer 141, and in some embodiments may be from about 0.5 wt % to about 5 wt %.

### 1-4-2. Configuration of Second Hole Transport Material Layer

In some embodiments, the second hole transport layer 142 is a layer adjacent to (e.g., directly contacting) the emission layer 150. The second hole transport layer 142 may include the second hole transport material. The second hole transport material may be represented by the following Formula 2:

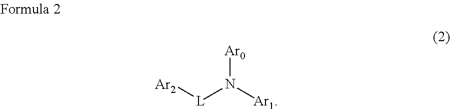

In the above Formula 2, Ar₀ to A₁ may each independently be selected from a substituted or unsubstituted aryl group and a substituted or unsubstituted heteroaryl group. Non-limiting examples of Ar₀ and Ar₁ may include a phenyl group, a naphthyl group, an anthracenyl group, a phenanthryl group, a biphenyl group, a terphenyl group, a fluorenyl group, a triphenylene group, a biphenylene group, a pyrenyl group, a benzothiazolyl group, a thiophenyl group, a thienothiophenyl group, a thienothienothiophenyl group, a benzothiophenyl group, a dibenzothiophenyl group, a N-arylcarbazolyl group, a N-heteroarylcarbazolyl group, a N-alkylcarbazolyl group, a phenoxazyl group, a phenothiazyl group, a pyridyl group, a pyrimidyl group, a triazile group, a quinolinyl group, a quinoxalyl group, and the like. In some embodiments, Ar₀ and Ar₁ may each independently be a substituted or unsubstituted aryl group, for example, a substituted or unsubstituted aryl group having 6 to 18 carbon atoms for forming a ring.

The substituents of Ar₀ and Ar₁ may include an alkyl group, an alkoxy group, an aryl group, a heteroaryl group, and/or the like. Non-limiting examples of the aryl group and the heteroaryl group may be as described above. Non-limiting examples of the alkyl group may include a methyl group, an ethyl group, a propyl group, an isopropyl group, a cyclopropyl group, a butyl group, an isobutyl group, a t-butyl group, a cyclobutyl group, a pentyl group, an isopentyl group, a neopentyl group, a cyclopentyl group, a hexyl group, a cyclohexyl group, a heptyl group, a cycloheptyl group, an octyl group, a nonyl group, a decyl group, and the like.

Non-limiting examples of the alkoxy group may include a methoxy group, an ethoxy group, a n-propoxy group, an isopropoxy group, a n-butoxy group, an isobutoxy group, a t-butoxy group, a n-pentyloxy group, a neopentyloxy group, a n-hexyloxy group, a n-heptyloxy group, a n-octyloxy group, a 2-ethylhexyloxy group, a nonyloxy group, a decyloxy group, a 3,7-dimethyloctyloxy group, and the like.

At least one selected from Ar₀ and Ar₁ may be substituted with a substituted or unsubstituted silyl group. The substituents of the substituted silyl group may be selected from an alkyl group, an alkoxy group, an aryl group, and a heteroaryl group. Non-limiting examples of the substituent groups may be as described above. In some embodiments, one or more substituents of the substituted silyl group may each independently be substituted with at least one selected from an alkyl group, an alkoxy group, an aryl group, and a heteroaryl group. Non-limiting examples of the substituent groups may be as described above. In some embodiments, the substituent of the substituted silyl group may be a substituted or unsubstituted aryl group, for example, an unsubstituted phenyl group. The silyl group may include, for example, a triphenylsilyl group.

Ar₂ may be a substituted or unsubstituted dibenzofuranyl group. The substituents of the dibenzofuranyl group may each independently be selected from an alkyl group, an alkoxy group, an aryl group, and a heteroaryl group. Non-limiting examples of the substituent groups may be as described above. In some embodiments, one or more substituents of the substituted dibenzofuranyl group may each independently be substituted with at least one selected from an alkyl group, an alkoxy group, an aryl group, and a heteroaryl group. Non-limiting examples of the substituent groups may be as described above. The position at which the dibenzofuranyl group is coupled with L is not specifically limited, and may be, for example, position 3 (e.g., L may be attached to a carbon atom at a third position in a ring of the dibenzofuranyl group). According to one or more embodiments of the present disclosure, the properties of the organic electroluminescent device may be further improved.

L may be selected from a direct linkage (e.g., a bond, such as a single bond), a substituted or unsubstituted arylene group, and a substituted or unsubstituted heteroarylene group. Non-limiting examples of the arylene group and the heteroarylene group may include the divalent versions of the example substituents provided in connection with Ar₀ and Ar₁. Non-limiting examples of the arylene group and the heteroarylene group may include a phenylene group, a naphthylene group, a biphenylene group, a thienothiophenylene group and pyridylene group. In some embodiments, L may be an arylene group having 6 to 14 carbon atoms for forming a ring, and in some embodiments, L may be selected from the phenylene group and the biphenylene group. In the embodiments where L is “a direct linkage” (e.g., a bond, such as a single bond), the dibenzofuranyl group and L may be directly linked.

The second hole transport material may include at least one compound represented by the following Formulae 2-1 to 2-34:

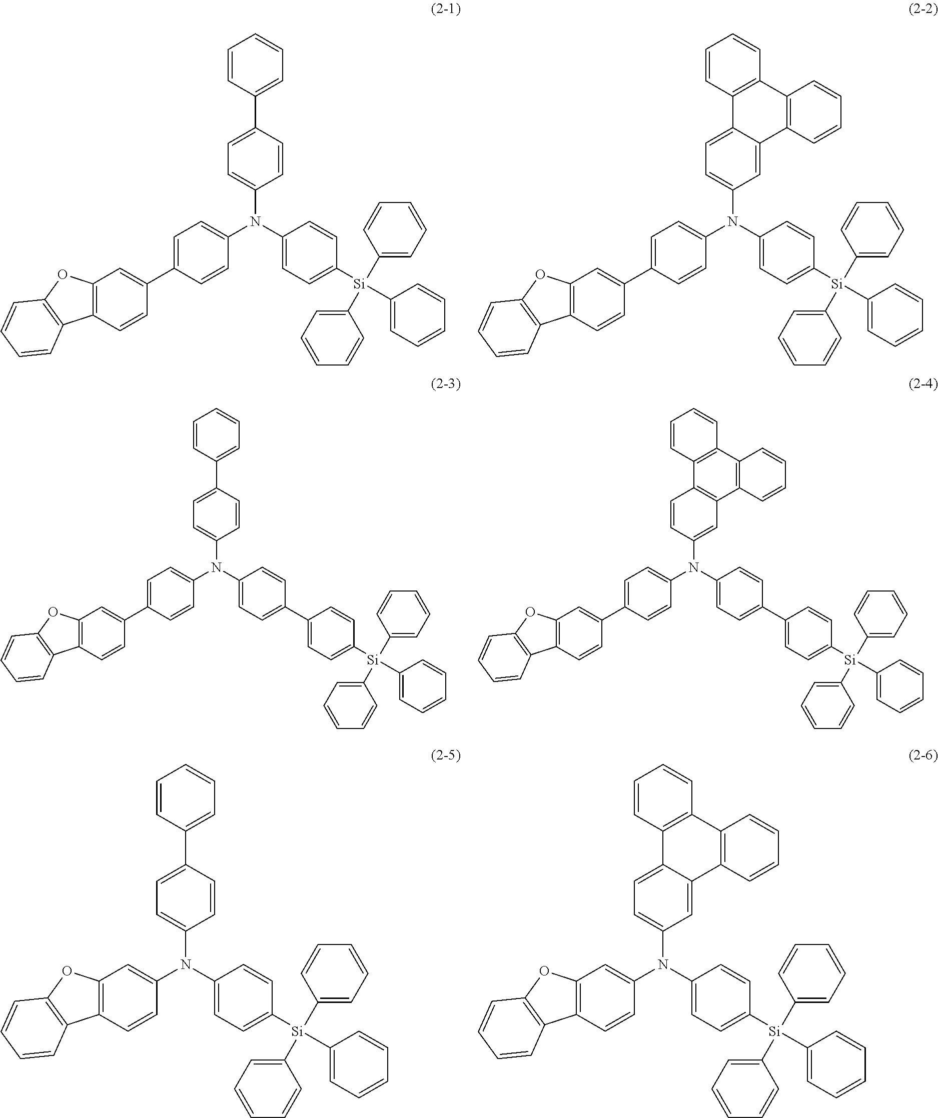

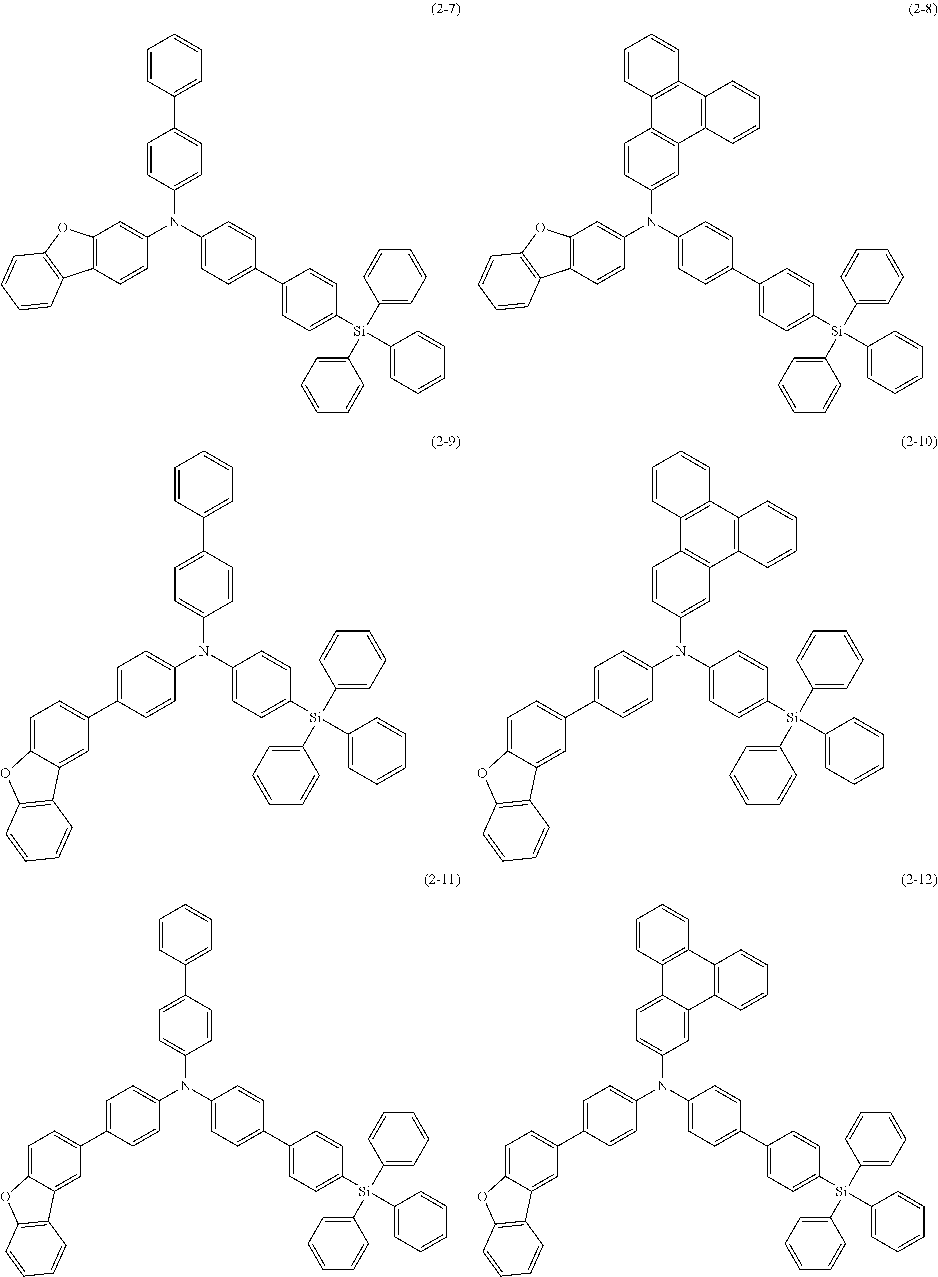

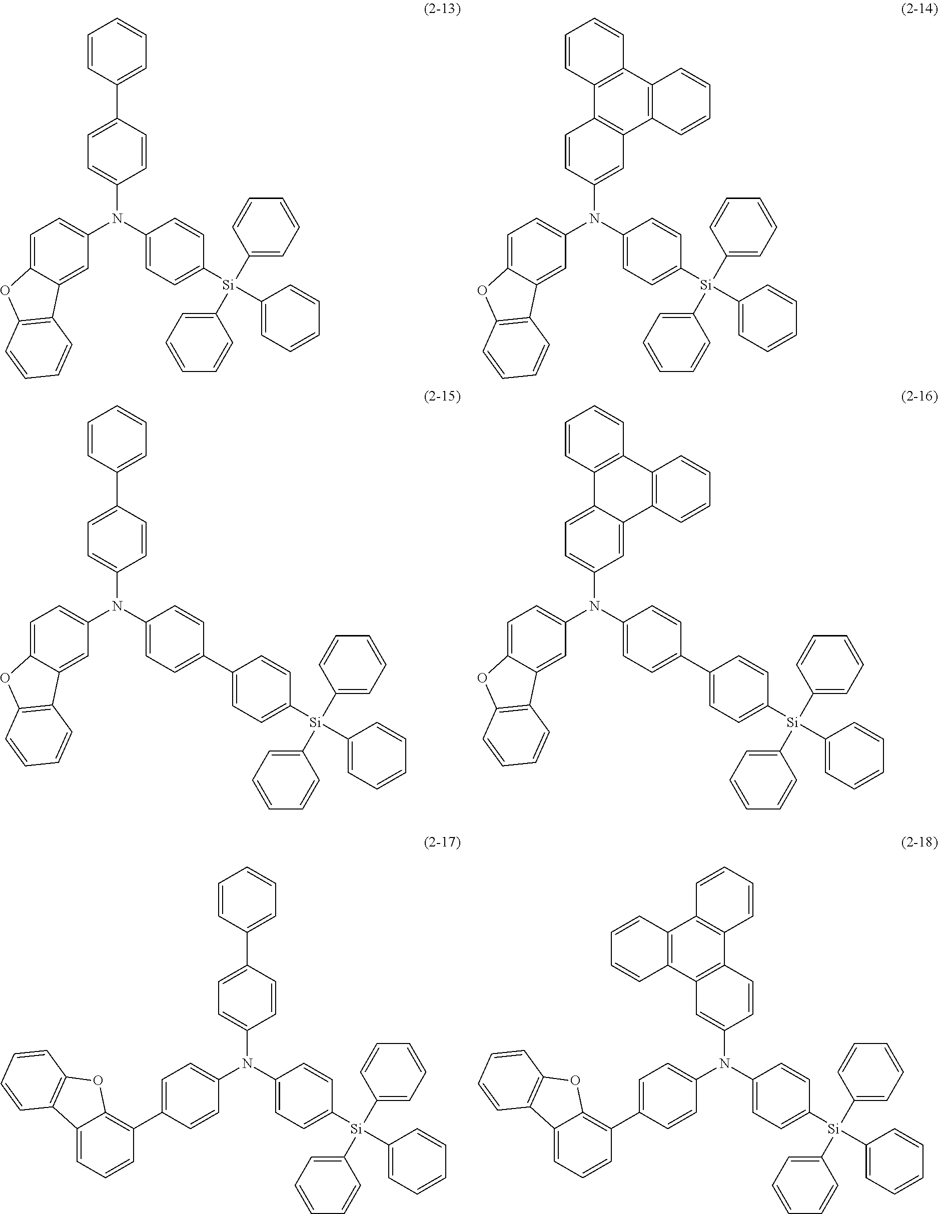

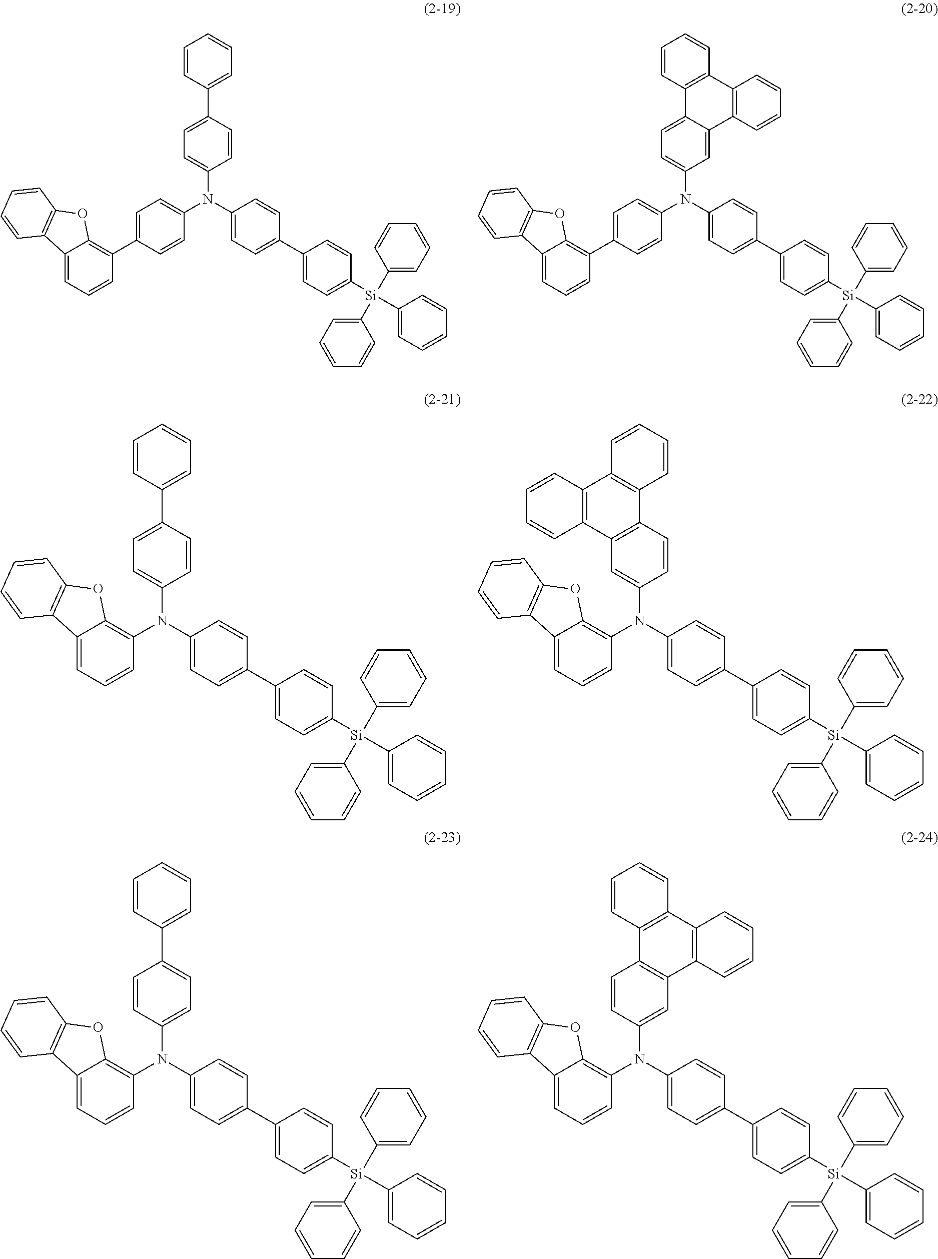

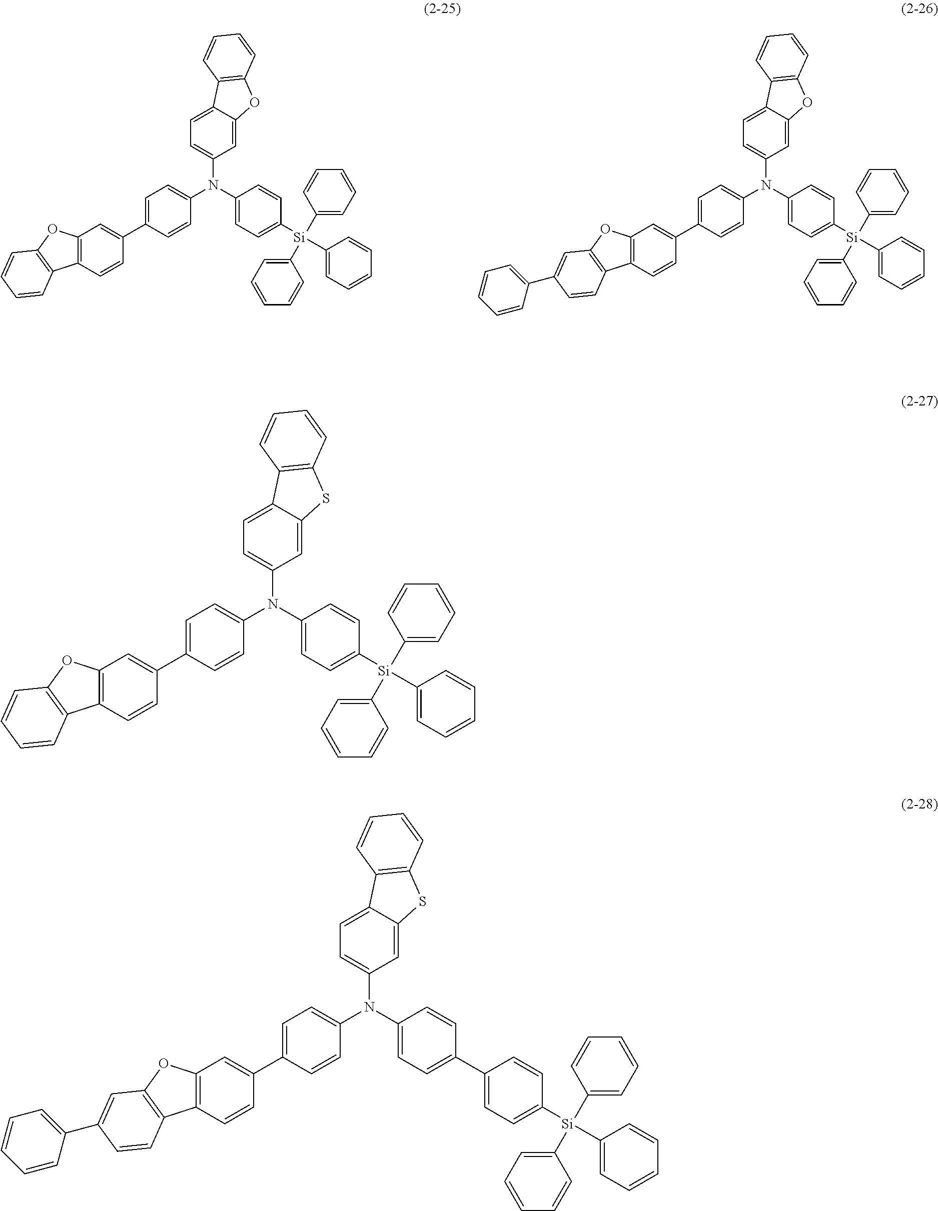 [SMILES: c1ccc([Si](c2ccccc2)(c2ccccc2)c2ccc(N(c3ccc(-c4ccc5c(c4)oc4ccccc45)cc3)c3ccc4c(c3)oc3ccccc34)cc2)cc1 ; c1ccc(-c2ccc3c(c2)oc2cc(-c4ccc(N(c5ccc([Si](c6ccccc6)(c6ccccc6)c6ccccc6)cc5)c5ccc6c(c5)oc5ccccc56)cc4)ccc23)cc1 ; c1ccc([Si](c2ccccc2)(c2ccccc2)c2ccc(N(c3ccc(-c4ccc5c(c4)oc4ccccc45)cc3)c3ccc4c(c3)sc3ccccc34)cc2)cc1 ; c1ccc(-c2ccc3c(c2)oc2cc(-c4ccc(N(c5ccc(-c6ccc([Si](c7ccccc7)(c7ccccc7)c7ccccc7)cc6)cc5)c5ccc6c(c5)sc5ccccc56)cc4)ccc23)cc1]

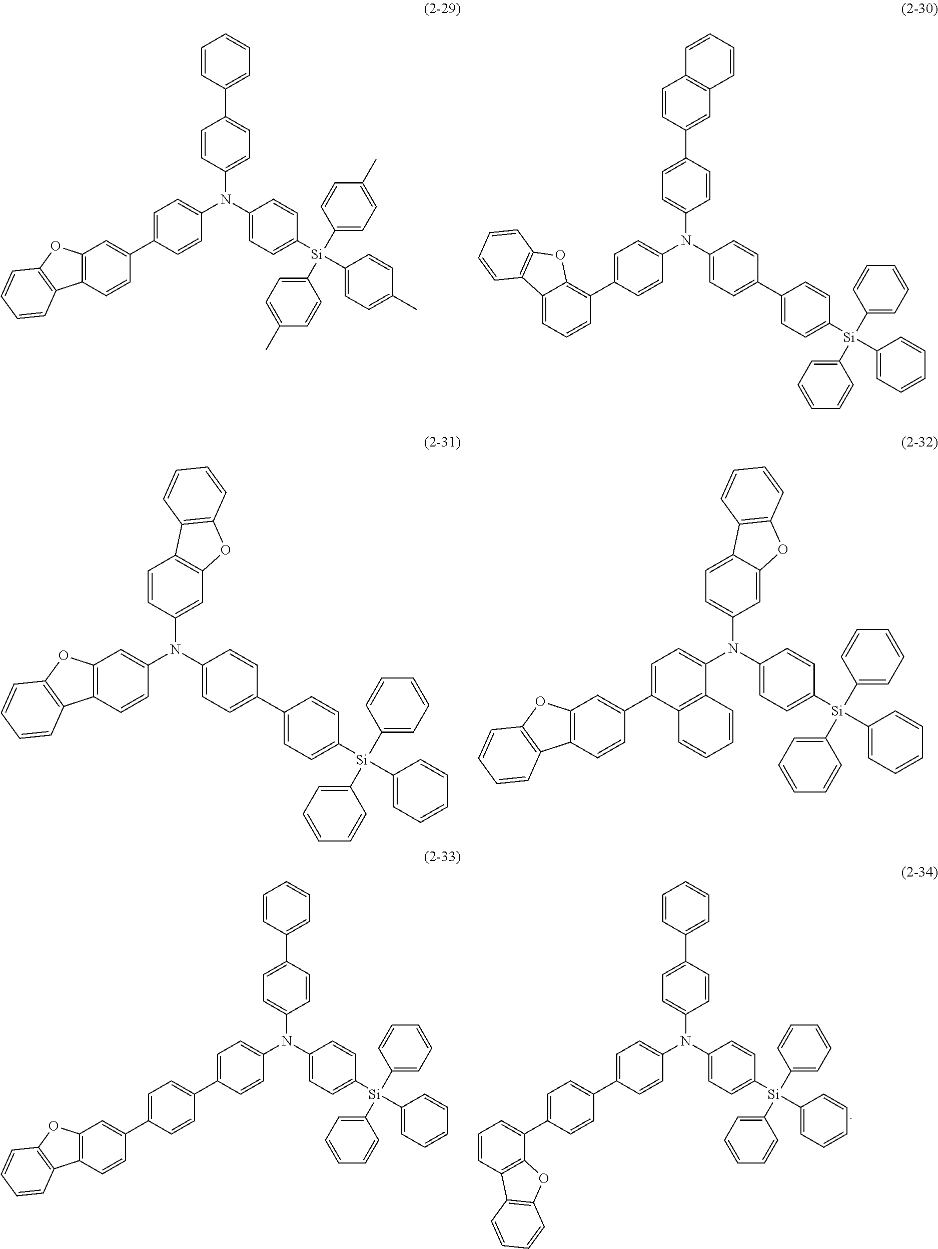

### 1-4-3. Configuration of Third Hole Transport Layer

The third hole transport layer 143 may be provided between the first hole transport layer 141 and the second hole transport layer 142. The third hole transport layer 143 may include at least one selected from the first hole transport material and the second hole transport material.

1-4-4. Modification Example of Hole Transport Layer

In some embodiments, the hole transport layer 140 may have a three-layer structure, however the configuration of the hole transport layer 140 is not limited thereto. For example, the hole transport layer 140 may have any suitable structure so long as the first hole transport layer 141 and the second hole transport layer 142 are positioned between the first electrode 120 and the emission layer 150. For example, as shown in FIG. 2, the third hole transport layer 143 may be omitted. In some embodiments, the stacking order of the first hole transport layer 141 and the second hole transport layer 142 may be exchanged (e.g., reversed). In some embodiments, the third hole transport layer 143 may be positioned between the first hole transport layer 141 and the first electrode 120. In some embodiments, the third hole transport layer 143 may be positioned between the second hole transport layer 142 and the emission layer 150. In some embodiments, the first, second, and third hole transport layers 141, 142, and 143 may each independently be formed as a multilayer structure.

### 1-5. Configuration of Emission Layer

In some embodiments, the emission layer 150 is a layer capable of emitting light via fluorescence or phosphorescence. The emission layer 150 may include a host material and a dopant material as a luminescent material. In some embodiments, the emission layer 150 may be formed to have a layer thickness from about 10 nm to about 60 nm.

The host material of the emission layer 150 may be represented by the following Formula 3:

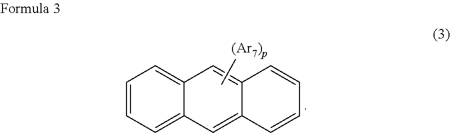

In the above Formula 3, each Ar₇ may be independently selected from a hydrogen atom, a deuterium atom, a substituted or unsubstituted alkyl group having 1 to 50 carbon atoms, a substituted or unsubstituted cycloalkyl group having 3 to 50 atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 atoms for forming a ring, a substituted or unsubstituted silyl group, a carboxyl group, a halogen atom, a cyano group, a nitro group, and a hydroxyl group, p may be an integer from 1 to 10.

The host material represented by Formula 3 may include at least one compound represented by any of the following Formulae 3-1 to 3-12:

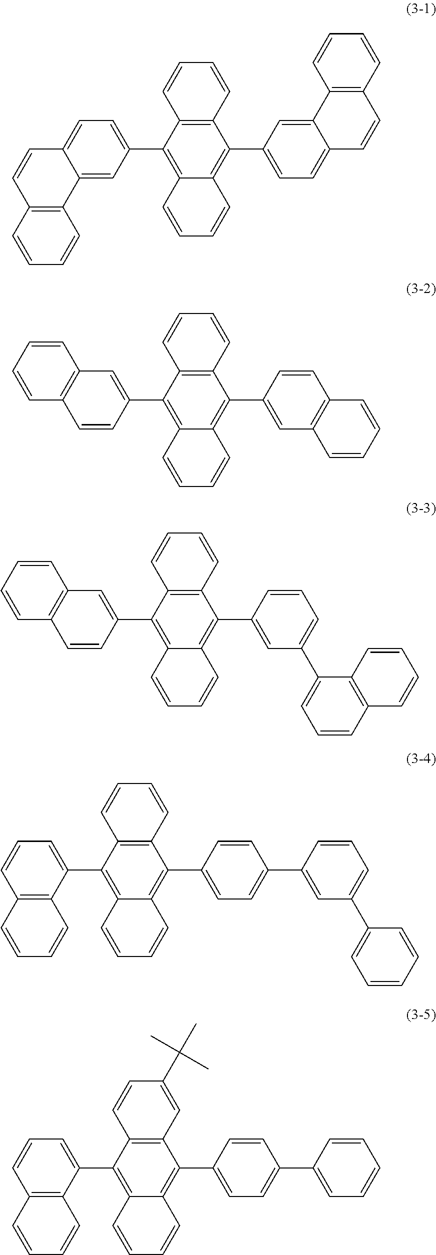

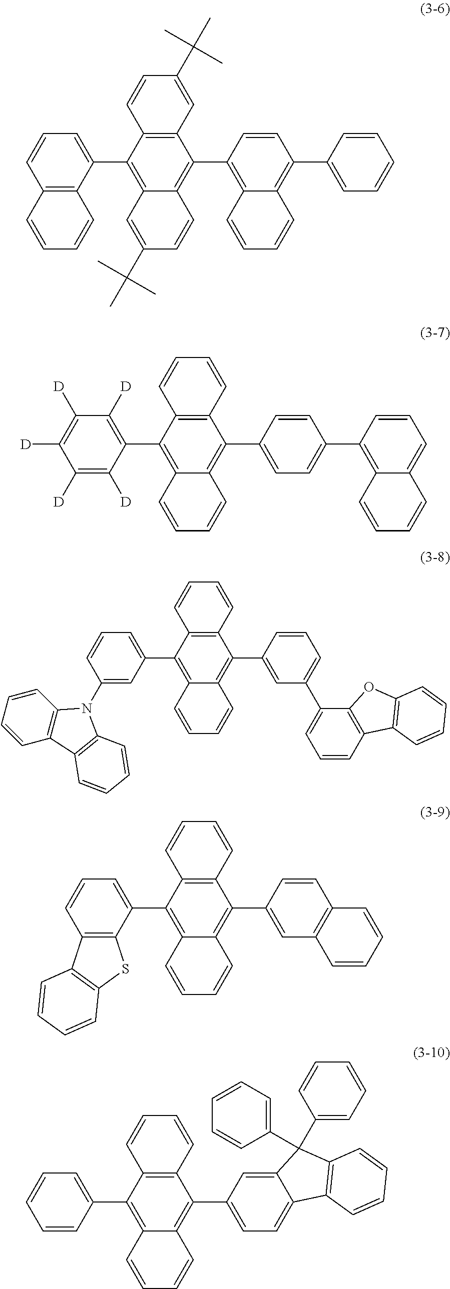

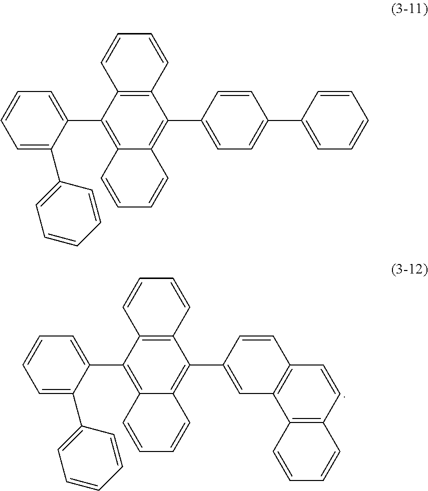

In some embodiments, the host material may include other host materials. Non-limiting examples of the other host materials may include tris(8-quinolinolato)aluminum (Alq3), 4,4′-N,N′-dicarbazole-biphenyl (CBP), poly(n-vinylcarbazole) (PVK), 9,10-di(naphtho-2-yl)anthracene (ADN), 4,4′,4″-tris(N-carbazolyl)triphenylamine (TCTA), 1,3,5-tris(N-phenylbenzimidazole-2-yl)benzene (TPBI), 3-tert-butyl-9,10-di(naphtho-2-yl)anthracene (TBADN), distyrylarylene (DSA), 4,4′-bis(9-carbazole)-2,2′-dimethyl-biphenyl (dmCBP), bis(2,2-diphenylvinyl)-1,1′-biphenyl (DPVBi, Formula 3-13 below), and the like. In some embodiments, the host material may be any suitable material capable of being used as the host material of an organic electroluminescent device.

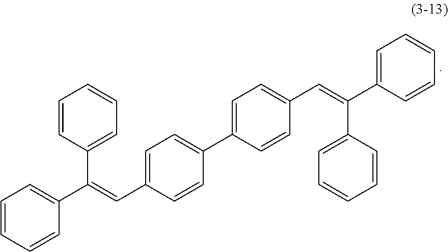 [SMILES: C(=C(c1ccccc1)c1ccccc1)c1ccc(-c2ccc(C=C(c3ccccc3)c3ccccc3)cc2)cc1]

In some embodiments, the emission layer 150 may be formed as an emission layer capable of emitting light with specific color. For example, the emission layer 150 may be formed as a red emitting layer, a green emitting layer, or a blue emitting layer.

When the emission layer 150 is the blue emitting layer, any suitable blue dopant generally available in the art of organic light-emitting devices may be used. For example, perylene and/or derivatives thereof, an iridium (Ir) complex (such as bis[2-(4,6-difluorophenyl)pyridinate]picolinate iridium(III) (Flrpic)), and/or the like may be used as the blue dopant.

When the emission layer 150 is the red emitting layer, any suitable red dopant generally available in the art of organic light-emitting devices may be used. For example, rubrene and/or derivatives thereof, 4-dicyanomethylene-2-(p-dimethylaminostyryl)-6-methyl-4H-pyrane (DCM) and/or derivatives thereof, an iridium complex (such as bis(1-phenylisoquinoline)(acetylacetonate) iridium(III) (Ir(piq)₂(acac)), an osmium (Os) complex, a platinum complex, and/or the like may be used as the red dopant.

When the emission layer 150 is the green emitting layer, any suitable green dopant generally available in the art of organic light-emitting devices may be used. For example, coumarin and/or derivatives thereof, an iridium complex (such as tris(2-phenylpyridine) iridium(III) (Ir(ppy)₃)), and/or the like may be used as the green dopant.

In some embodiments, the electron transport layer 160 is a layer including an electron transport material and having electron transporting function. The electron transport layer 160 may be formed, for example, on the emission layer 150 to a layer thickness from about 15 nm to about 50 nm. The electron transport layer 160 may be formed using any suitable electron transport material generally available in the art of organic light-emitting devices. Non-limiting examples of the electron transport material may include a quinoline derivative such as tris(8-quinolinolato)aluminum (Alq3), a 1,2,4-triazole derivative (TAZ), bis(2-methyl-8-quinolinolato)-(p-phenylphenolate)-aluminum (BAlq), berylliumbis(benzoquinoline-10-olate) (BeBq2), a L₁ complex such as lithium quinolate (LiQ), and the like.

In some embodiments, the electron injection layer 170 is a layer that is capable of facilitating the injection of electrons from the second electrode 180, and the electron injection layer 170 may be formed to a layer thickness from about 0.3 nm to about 9 nm. The electron injection layer 170 may be formed using any suitable material that may be used as a material for forming an electron injection layer, and non-limiting examples thereof may include lithium fluoride (LiF), sodium chloride (NaCl), cesium fluoride (CsF), lithium oxide (Li₂O), barium oxide (BaO), and the like.

The second electrode 180 may be, for example, a cathode. In some embodiments, the second electrode 180 may be formed as a reflection type electrode using a metal, an alloy, a conductive compound, and/or the like, having small work function. For example, the second electrode 180 may be formed using one or more selected from lithium (Li), magnesium (Mg), aluminum (Al), aluminum-lithium (Al—Li), calcium (Ca), magnesium-indium (Mg—In), magnesium-silver (Mg—Ag), and the like. In some embodiments, the second electrode 180 may be formed as a transmission type electrode using ITO, IZO, and/or the like. The second electrode 180 may be formed on the electron injection layer 170 using, for example, an evaporation method (e.g., an evaporation deposition method) or a sputtering method.

### 1-6. Modification Example of Organic Electroluminescent Device

Although in the embodiment of FIG. 1, layers other than the hole transport layer 140 are illustrated as having a single layer structure, the layers may each independently have a multilayer structure. In some embodiments, in the organic electroluminescent device 100, a hole injection layer may be further provided between the hole transport layer 140 and the first electrode 120.

In some embodiments, the hole injection layer is a layer that is capable of facilitating the injection of holes from the first electrode 120, and the hole injection layer may be formed, for example, on the first electrode 120 to a layer thickness from about 10 nm to about 150 nm. A hole injection material constituting the hole injection layer is not specifically limited. Non-limiting examples of the hole injection material may include a triphenylamine-containing polyether ketone (herein, TPAPEK), 4-isopropyl-4′-methyldiphenyliodonium tetrakis(pentafluorophenyl)borate (herein, PPBI), N,N′-diphenyl-N,N′-bis-[4-(phenyl-m-tolyl-amino)-phenyl]-biphenyl-4,4′-diamine (herein, DNTPD), a phthalocyanine compound such as copper phthalocyanine, and/or the like, 4,4′,4″-tris(3-methylphenylphenylamino)triphenylamine (m-MTDATA), N,N′-di(1-naphthyl)-N,N′-diphenylbenzidine (NPB), 4,4′,4″-tris{N,N-diphenylamino}triphenylamine (TDATA), 4,4′,4″-tris(N,N-2-naphthylphenylamino)triphenylamine (2-TNATA), polyaniline/dodecylbenzenesulfonic acid (Pani/DBSA), poly(3,4-ethylenedioxythiophene)/poly(4-styrenesulfonate) (PEDOT/PSS), polyaniline/camphorsulfonic acid (Pani/CSA), polyaniline/poly(4-styrenesulfonate (PANI/PSS), and the like.

In some embodiments, in the organic electroluminescent device 100, at least one selected from the electron transport layer 160 and the electron injection layer 170 not be provided.

### EXAMPLES

Hereinafter, organic electroluminescent device according to one or more embodiments of the present disclosure will be explained in more detail by referring to Examples and Comparative Examples. It will be understood that the following examples are provided for illustrative purposes only, and should not be interpreted as limiting the scope of the present disclosure.

### Synthetic Example 1

### Synthesis of Compound Represented by Formula 2-3

According to the following reaction scheme, Compound 2-3 represented by Formula 2-3 was synthesized.

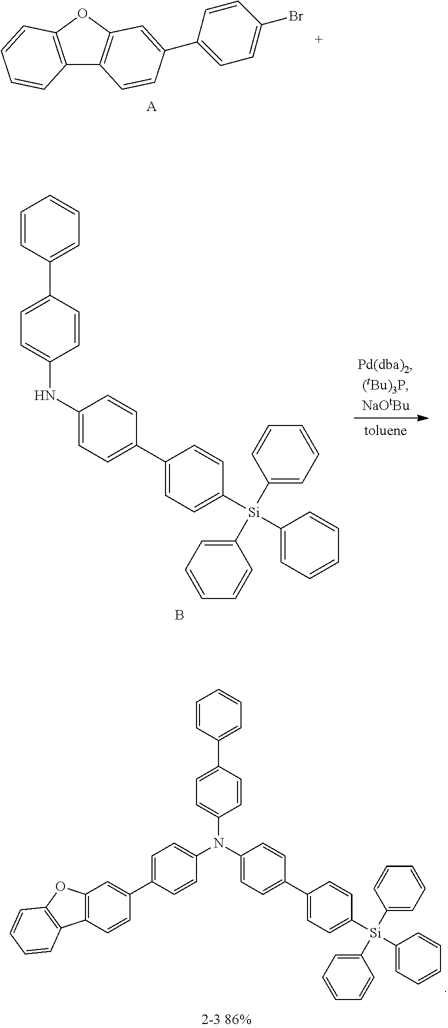

Compound 2-3 was synthesized according to the following procedure. Under an argon atmosphere, 1.50 g of Compound A, 1.90 g of Compound B, 0.11 g of bis(dibenzylideneacetone)palladium(0) (Pd(dba)₂), 0.15 g of tri-tert-butylphosphine ((t-Bu)₃P) and 0.54 g of sodium tert-butoxide were added to a 100 mL, three necked flask, followed by heating and refluxing the resulting mixture in 45 mL of a toluene solvent for about 6 hours. After air cooling, water was added to the resulting solution to separate an organic layer, and solvent was distilled. The crude product thus obtained was separated using silica gel column chromatography (using a mixture solvent of dichloromethane and hexane) and recrystallized using a mixture solvent of toluene and hexane to produce 1.86 g of a target product as a white solid (Yield 86%).

The chemical shift values of the target product measured by ¹H NMR were 8.000 (d, 1H), 7.96 (d, 1H), 7.78 (d, 1H), 7.64-7.53 (m, 20H), 7.48-7.33 (m, 14H), 7.29-7.25 (m, 6H). In addition, the molecular weight of the target product measured by Fast Atom Bombardment Mass Spectrometry (FAB-MS) was about 822. From the results, the target product was confirmed to be Compound 2-3.

### Synthetic Example 2

### Synthesis of Compound Represented by Compound 2-9

According to the following reaction scheme, Compound 2-9 represented by Formula 2-9 was synthesized.

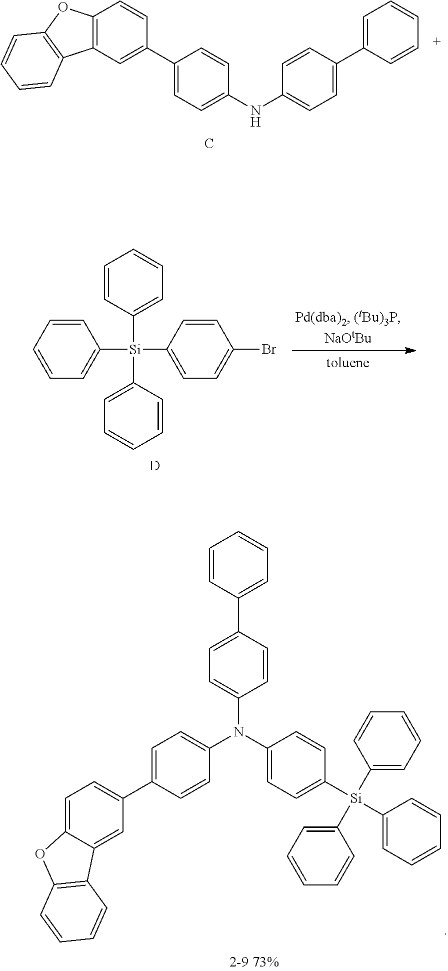

Compound 2-9 was synthesized according to the following procedure. Under an argon atmosphere, 2.50 g of Compound C, 2.52 g of Compound D, 0.25 g of bis(dibenzylideneacetone)palladium(0) (Pd(dba)₂), 0.10 g of tri-tert-butylphosphine ((t-Bu)₃P) and 1.85 g of sodium tert-butoxide were added to a 100 mL, three necked flask, followed by heating and refluxing the resulting mixture in 60 ml of a toluene solvent for about 8 hours. After air cooling, water was added to the resulting solution to separate an organic layer, and solvent was distilled. The crude product thus obtained was separated using silica gel column chromatography (using a mixture solvent of dichloromethane and hexane) and recrystallized using a mixture solvent of toluene and hexane to produce 3.31 g of a target product as a white solid (Yield 73%).

The chemical shift values of the target product measured by ¹H NMR were 8.13 (d, 1H), 7.98 (d, 1H), 7.69-7.24 (m, 35H), 7.16 (d, 2H). In addition, the molecular weight of the target product measured by FAB-MS was about 745. From the results, the target product was confirmed to be Compound 2-9.

### Synthetic Example 3

### Synthesis of Compound Represented by Formula 2-17

According to the following reaction scheme, Compound 2-17 represented by Formula 2-17 was synthesized.

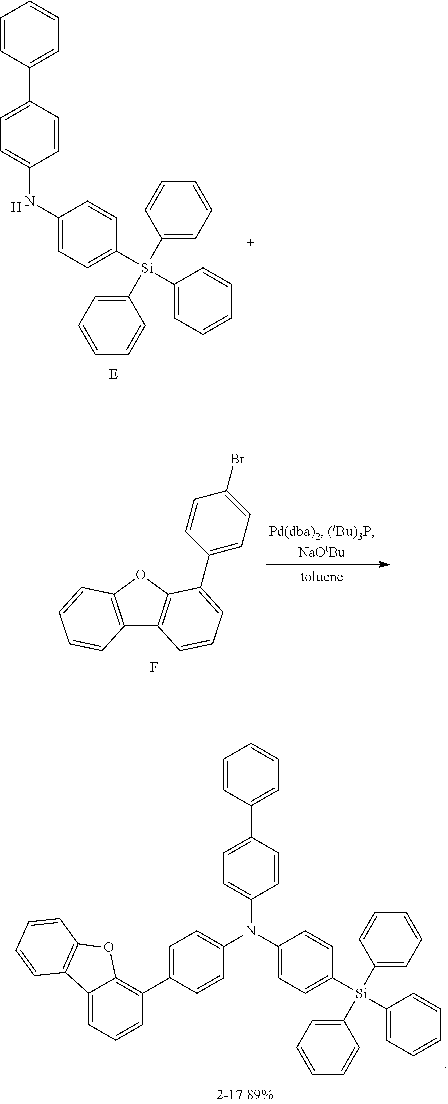

Compound 2-17 was synthesized according to the following procedure. Under an argon atmosphere, 0.8 g of Compound E, 0.54 g of Compound F, 0.06 g of bis(dibenzylideneacetone)palladium(0) (Pd(dba)₂), 0.12 g of tri-tert-butylphosphine ((t-Bu)₃P) and 0.3 g of sodium tert-butoxide were added to a 100 mL, three necked flask, followed by heating and refluxing the resulting mixture in 30 ml of a toluene solvent for about 7 hours. After air cooling, water was added to the resulting solution to separate an organic layer, and solvent was distilled. The crude product thus obtained was separated using silica gel column chromatography (using a mixture solvent of dichloromethane and hexane) and recrystallized using a mixture solvent of toluene and hexane to produce 0.95 g of a target product as a white solid (Yield 89%).

The chemical shift values of the target product measured by ¹H NMR were 7.99 (d, 1H), 7.91 (d, 1H), 7.87 (d, 2H), 7.62-7.28 (m, 33H), 7.20 (d, 2H). In addition, the molecular weight of the target product measured by FAB-MS was about 745. From the results, the target product was confirmed to be Compound 2-17.

### Synthetic Example 4

### Synthesis of Compound Represented by Formula 2-19

According to the following reaction scheme, Compound 2-19 represented by Formula 2-19 was synthesized.

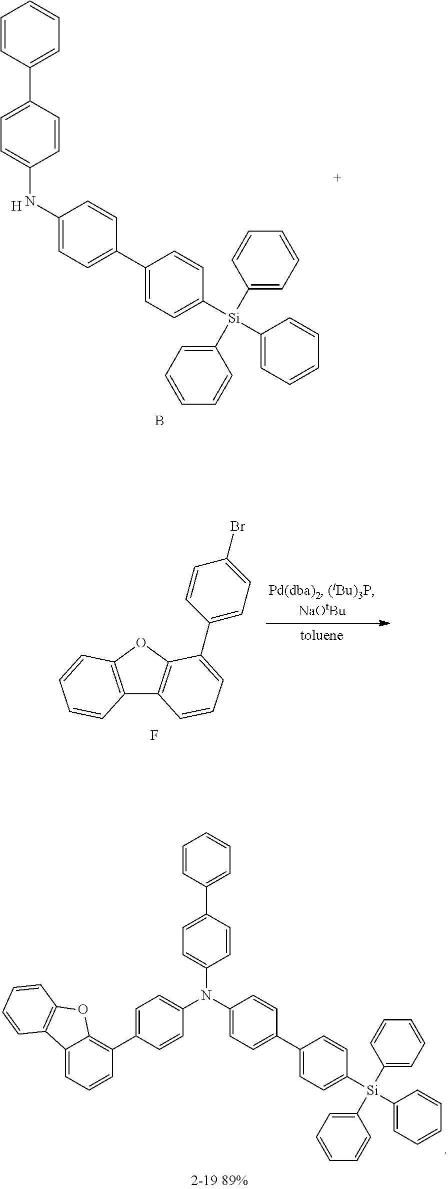

Compound 2-19 was synthesized according to the following procedure. Under an argon atmosphere, 1.50 g of Compound B, 0.87 g of Compound F, 0.11 g of bis(dibenzylideneacetone)palladium(0) (Pd(dba)₂), 0.15 g of tri-tert-butylphosphine ((t-Bu)₃P) and 0.54 g of sodium tert-butoxide were added to a 100 mL, three necked flask, followed by heating and refluxing the resulting mixture in 45 ml of a toluene solvent for about 7 hours. After air cooling, water was added to the resulting solution to separate an organic layer, and solvent was distilled. The crude product thus obtained was separated using silica gel column chromatography (using a mixture solvent of dichloromethane and hexane) and recrystallized using a mixture solvent of toluene and hexane to produce 1.86 g of a target product as a white solid (Yield 89%).

The chemical shift values of the target product measured by ¹H NMR were 8.000 (d, 1H), 7.93-7.87 (m, 3H), 7.66-7.53 (m, 17H), 7.50-7.28 (m, 22H). In addition, the molecular weight of the target product measured by FAB-MS was about 822. From the results, the target product was confirmed to be Compound 2-19.

### Synthetic Example 5

### Synthesis of Compound Represented by Formula 2-25

According to the following reaction scheme, Compound 2-25 represented by Formula 2-25 was synthesized.

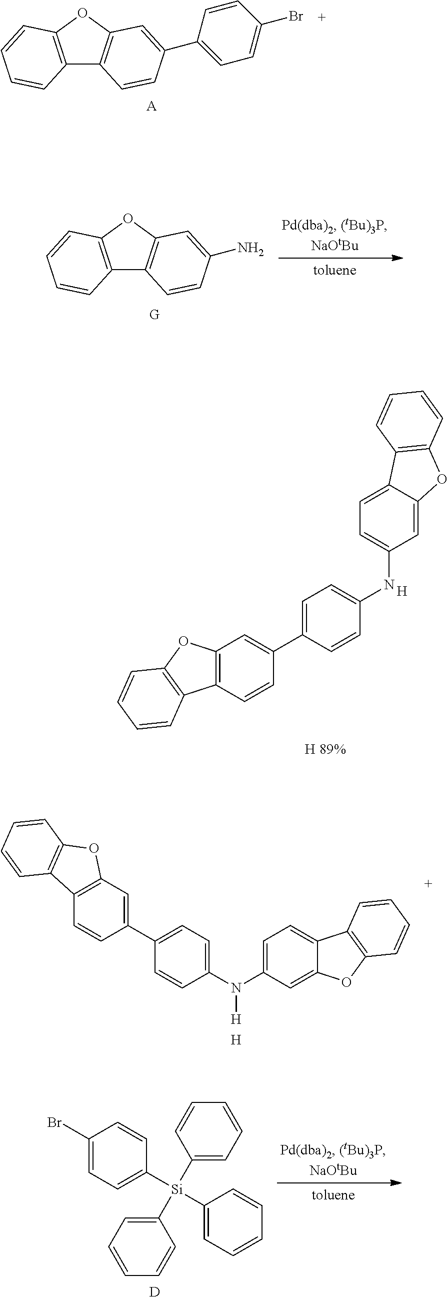

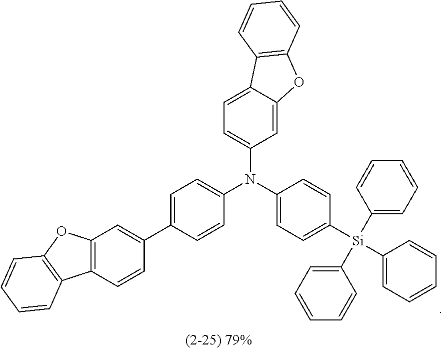 [SMILES: c1ccc([Si](c2ccccc2)(c2ccccc2)c2ccc(N(c3ccc(-c4ccc5c(c4)oc4ccccc45)cc3)c3ccc4c(c3)oc3ccccc34)cc2)cc1]

Compound 2-25 was synthesized according to the following procedure. Under an argon atmosphere, 3.00 g of Compound A, 1.68 g of Compound G, 0.20 g of bis(dibenzylideneacetone)palladium(0) (Pd(dba)₂), 0.25 g of tri-tert-butylphosphine ((t-Bu)₃P) and 0.78 g of sodium tert-butoxide were added to a 100 mL, three necked flask, followed by heating and refluxing the resulting mixture in 80 ml of a toluene solvent for about 7 hours. After air cooling, water was added to the resulting solution to separate an organic layer, and solvent was distilled. The crude product thus obtained was separated using silica gel column chromatography (using a mixture solvent of dichloromethane and hexane) and recrystallized using a mixture solvent of toluene and hexane to produce 3.52 g of a target product as a white solid (Yield 89%).

The chemical shift values of the target product measured by ¹H NMR were 8.36 (s, 1H), 8.003 (s, 2H), 7.98-7.76 (m, 5H), 7.55-7.37 (m, 8H), 7.31-7.29 (m, 2H), 6.91 (d, 1H). In addition, the molecular weight of the target product measured by FAB-MS was about 425. From the results, the target product was confirmed to be Compound H.

Under an argon atmosphere, 3.52 g of Compound H, 3.44 g of Compound D, 0.25 g of bis(dibenzylideneacetone)palladium(0) (Pd(dba)₂), 0.28 g of tri-tert-butylphosphine ((t-Bu)₃P) and 1.90 g of sodium tert-butoxide were added to a 100 mL, three necked flask, followed by heating and refluxing the resulting mixture in 80 ml of a toluene solvent for about 7 hours. After air cooling, water was added to the resulting solution to separate an organic layer, and solvent was distilled. The crude product thus obtained was separated using silica gel column chromatography (using a mixture solvent of dichloromethane and hexane) and recrystallized using a mixture solvent of toluene and hexane to produce 4.97 g of a target product as a white solid (Yield 79%).

The chemical shift values of the target product measured by ¹H NMR were 8.003-7.97 (m, 2H), 7.98-7.76 (m, 5H), 7.55-7.31 (m, 29H), 6.91 (d, 1H). In addition, the molecular weight of the target product measured by FAB-MS was about 760. From the results, the target product was confirmed to be Compound 2-25.

### Synthetic Example 6

### Synthesis of Compound Represented by Formula 2-28

According to the following reaction scheme, Compound 2-28 represented by Formula 2-28 was synthesized.

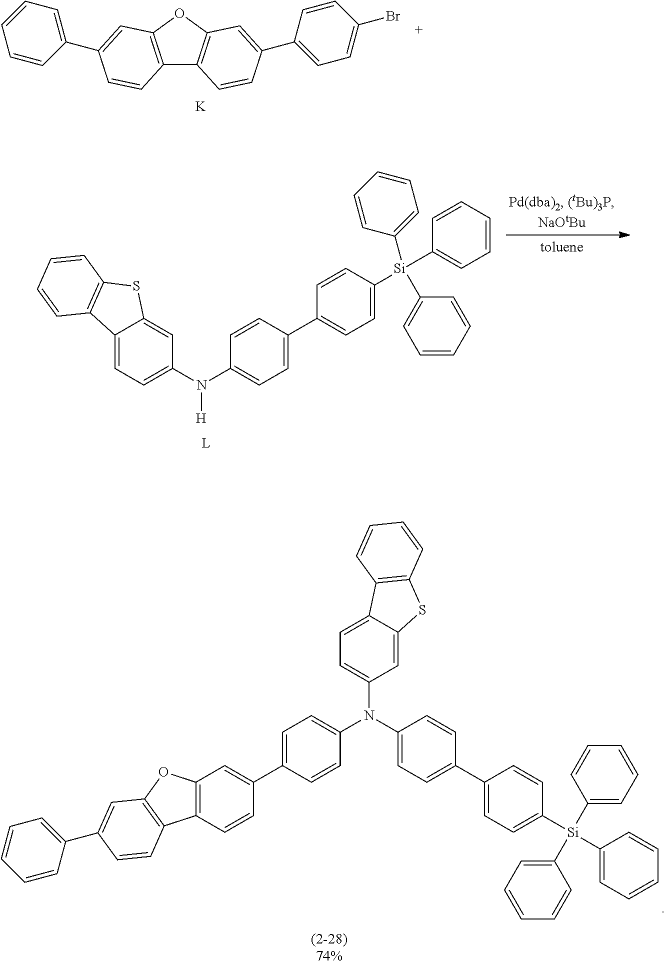

Compound 2-28 was synthesized according to the following procedure. Under an argon atmosphere, 1.50 g of Compound K, 2.55 g of Compound L, 0.20 g of bis(dibenzylideneacetone)palladium(0) (Pd(dba)₂), 0.30 g of tri-tert-butylphosphine ((t-Bu)₃P) and 0.76 g of sodium tert-butoxide were added to a 100 mL, three necked flask, followed by heating and refluxing the resulting mixture in 80 ml of a toluene solvent for about 7 hours. After air cooling, water was added to the resulting solution to separate an organic layer, and solvent was distilled. The crude product thus obtained was separated using silica gel column chromatography (using a mixture solvent of dichloromethane and hexane) and recrystallized using a mixture solvent of toluene and hexane to produce 2.5 g of a target product as a white solid (Yield 74%).

The chemical shift values of the target product measured by ¹H NMR were 8.45 (d, 1H), 8.004-8.000 (m, 3H), 7.93-7.75 (m, 9H), 7.64-7.46 (m, 3H), 7.56-7.38 (m, 29H). In addition, the molecular weight of the target product measured by FAB-MS was about 928. From the results, the target product was confirmed to be Compound 2-28.

### Synthetic Example 7

### Synthesis of Compound Represented by Formula 2-29

According to the following reaction scheme, Compound 2-29 represented by Formula 2-29 was synthesized.

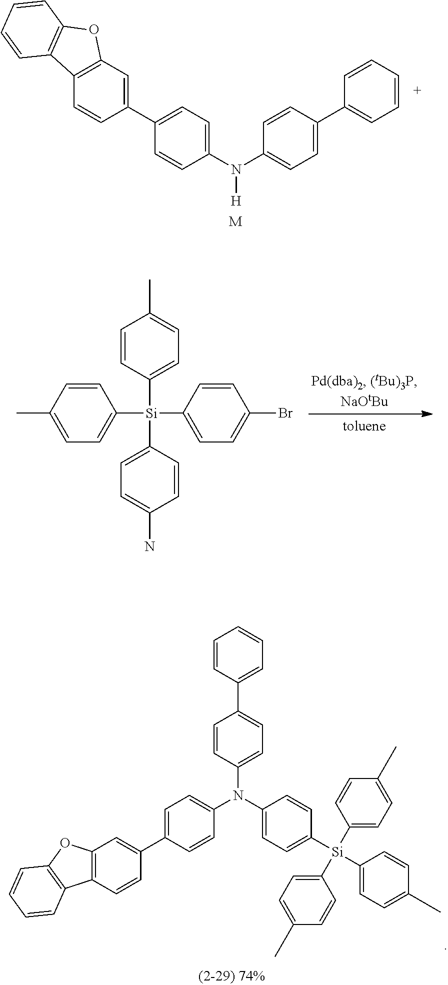

Compound 2-29 was synthesized according to the following procedure. Under an argon atmosphere, 1.50 g of Compound M, 1.99 g of Compound N, 0.18 g of bis(dibenzylideneacetone)palladium(0) (Pd(dba)₂), 0.32 g of tri-tert-butylphosphine ((t-Bu)₃P) and 0.77 g of sodium tert-butoxide were added to a 100 mL, three necked flask, followed by heating and refluxing the resulting mixture in 80 ml of a toluene solvent for about 7 hours. After air cooling, water was added to the resulting solution to separate an organic layer, and solvent was distilled. The crude product thus obtained was separated using silica gel column chromatography (using a mixture solvent of dichloromethane and hexane) and recrystallized using a mixture solvent of toluene and hexane to produce 2.5 g of a target product as a white solid (Yield 74%).

The chemical shift values of the target product measured by ¹H NMR were 8.003-7.97 (m, 2H), 7.82 (d, 1H), 7.76-7.75 (m, 3H), 7.55-7.26 (m, 30H), 2.37 (s, 9H). In addition, the molecular weight of the target product measured by FAB-MS was about 788. From the results, the target product was confirmed to be Compound 2-29.

### Synthetic Example 8

### Synthesis of Compound Represented by Formula 2-31

According to the following reaction scheme, Compound 2-31 represented by Formula 2-31 was synthesized.

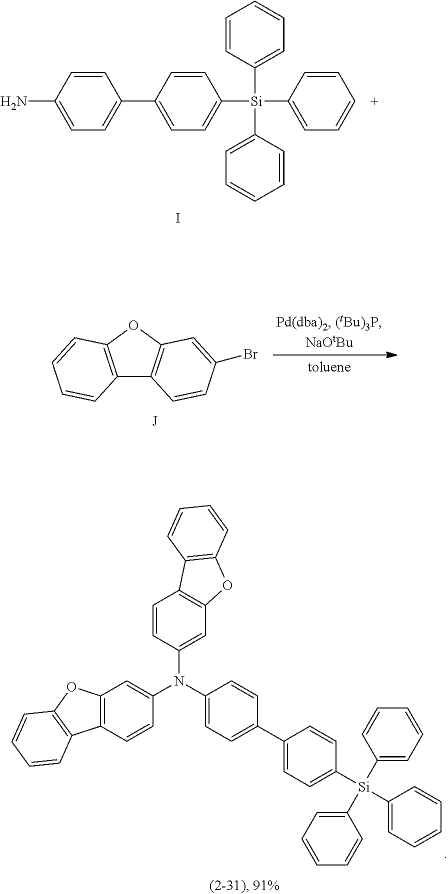

Compound 2-31 was synthesized according to the following procedure. Under an argon atmosphere, 2.00 g of Compound I, 1.15 g of Compound J, 0.18 g of bis(dibenzylideneacetone)palladium(0) (Pd(dba)₂), 0.22 g of tri-tert-butylphosphine ((t-Bu)₃P) and 0.65 g of sodium tert-butoxide were added to a 100 mL, three necked flask, followed by heating and refluxing the resulting mixture in 80 ml of a toluene solvent for about 7 hours. After air cooling, water was added to the resulting solution to separate an organic layer, and solvent was distilled. The crude product thus obtained was separated using silica gel column chromatography (using a mixture solvent of dichloromethane and hexane) and recrystallized using a mixture solvent of toluene and hexane to produce 3.23 g of a target product as a white solid (Yield 91%).

The chemical shift values of the target product measured by ¹H NMR were 8.004-7.98 (m, 4H), 7.88-7.79 (m, 4H), 7.65-7.29 (m, 27H), 6.91 (d, 2H). In addition, the molecular weight of the target product measured by FAB-MS was about 760. From the results, the target product was confirmed to be Compound 2-31.

### Synthetic Example 9

### Synthesis of Compound Represented by Formula 2-33

According to the following reaction scheme, Compound 2-33 represented by Formula 2-33 was synthesized.

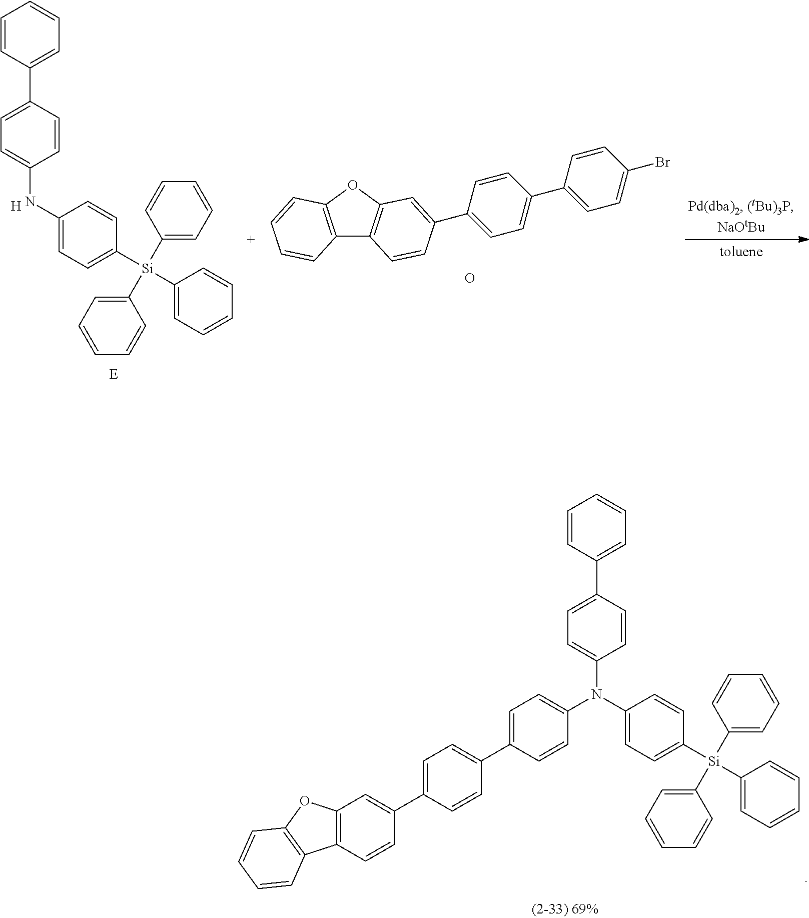

Compound 2-33 was synthesized according to the following procedure. Under an argon atmosphere, 1.50 g of Compound E, 1.42 g of Compound O, 0.21 g of bis(dibenzylideneacetone)palladium(0) (Pd(dba)₂), 0.33 g of tri-tert-butylphosphine ((t-Bu)₃P) and 0.83 g of sodium tert-butoxide were added to a 100 mL, three necked flask, followed by heating and refluxing the resulting mixture in 80 ml of a toluene solvent for about 7 hours. After air cooling, water was added to the resulting solution to separate an organic layer, and solvent was distilled. The crude product thus obtained was separated using silica gel column chromatography (using a mixture solvent of dichloromethane and hexane) and recrystallized using a mixture solvent of toluene and hexane to produce 1.68 g of a target product as a white solid (Yield 69%).

The chemical shift values of the target product measured by ¹H NMR were 8.003 (d, 1H), 7.97 (d, 1H), 7.84 (d, 1H), 7.76-7.75 (m, 3H) 7.73-7.25 (m, 37H). In addition, the molecular weight of the target product measured by FAB-MS was about 822. From the results, the target product was confirmed to be Compound 2-33.

### Manufacturing Example 1 of Organic Electroluminescent Device

An organic electroluminescent device was manufactured by the following manufacturing method. First, with respect to an ITO-glass substrate patterned and washed in advance, surface treatment using UV-Ozone (O₃) was conducted. The layer thickness of the resulting ITO layer (herein, used as a first electrode) was about 150 nm. After ozone treatment, the substrate was washed. After finishing washing, the substrate was inserted into a glass bell jar type (or kind) evaporator for forming an organic layer, and HTL1, HTL2, HTL3, an emission layer, and an electron transport layer were deposited on the substrate by evaporation deposition one by one at a vacuum degree of about 10⁻⁴ to about 10⁻⁵ Pa. The layer thickness of each of HTL1, HTL2 and HTL3 was about 10 nm. The layer thickness of the emission layer was about 25 nm, and the layer thickness of the electron transport layer was about 25 nm. Then, the substrate was moved into a glass bell jar type (or kind) evaporator for forming a metal layer, and an electron injection layer and a material for forming a cathode (herein, used as a second electrode) were deposited by evaporation deposition at a vacuum degree of about 10⁻⁴ to about 10⁻⁵ Pa. The layer thickness of the electron injection layer was about 1.0 nm and the layer thickness of the second electrode was about 100 nm.

Here, “HTL1”, “HTL2” and “HTL3” correspond to the hole transport materials including the compounds as shown in Table 1. In Table 1, the expression “Compound 1-3, 4-15” refers to a first hole transport material of Compound 1-3 doped with an electron accepting material of Compound 4-15. The doping amount of Compound 4-15 was about 3 wt % based on the total amount of Compound 1-3. The doping amount of the electron accepting material was the same in each Example and Comparative Example. Compounds 6-1 to 6-3 in Table 1 are represented by the following Formulae 6-1 to 6-3:

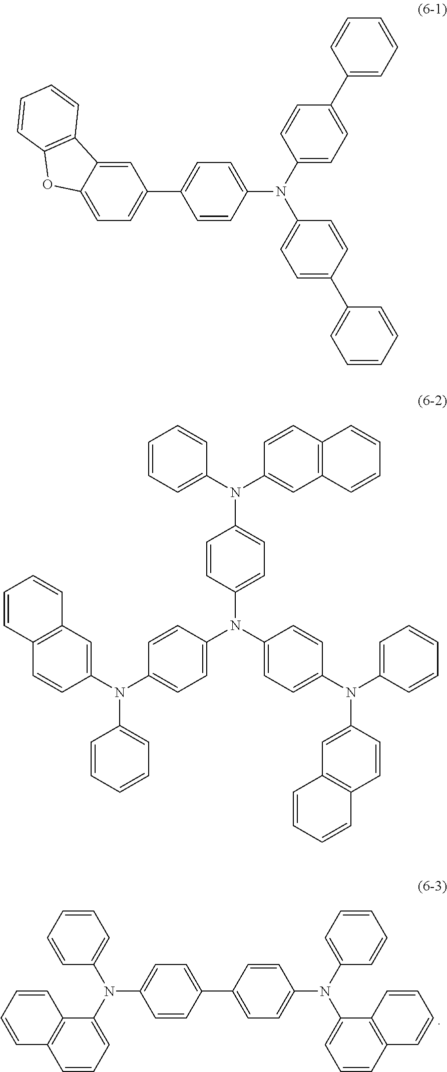 [SMILES: c1ccc(-c2ccc(N(c3ccc(-c4ccccc4)cc3)c3ccc(-c4ccc5oc6ccccc6c5c4)cc3)cc2)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1]

In Examples 1-14 and Comparative Examples 1-5, the host of the luminescent material was 9,10-di(2-naphthyl)anthracene (ADN, Compound 3-2) or bis(2,2-diphenylvinyl)-1,1′-biphenyl (DPVBi, Compound 3-13). The dopant was 2,5,8,11-tetra-t-butylperylene (TBP). The dopant material was added in an amount of about 3 wt % based on the total amount of the host. Alq3 was used as the electron transport material, and LiF was used as the electron injection material. Al was used as the second electrode material.

TABLE 1

| | First Hole | Third Hole | Second Hole | | | | |
|---|---|---|---|---|---|---|---|
| | Transport Layer | Transport Layer | Transport Layer | | | | Half |
| Device | (HTL1 hole | (HTL2 hole | (HTL3 hole | | | Emission | Life |
| manufacturing | transport | transport | transport | Host | Voltage | efficiency | LT50 |
| Example | material) | material) | material) | material | (V) | (cd/A) | (h) |
| Example 1 | Compound 1-3 | Compound 1-3 | Compound 2-3 | ADN | 6.3 | 7.7 | 3,300 |
| | Compound 4-15 | | | | | | |
| Example 2 | Compound 1-3 | Compound 1-3 | Compound 2-9 | ADN | 6.3 | 7.5 | 2,200 |
| | Compound 4-15 | | | | | | |
| Example 3 | Compound 1-3 | Compound 1-3 | Compound 2-17 | ADN | 6.4 | 7.5 | 2,400 |
| | Compound 4-15 | | | | | | |
| Example 4 | Compound 1-3 | Compound 1-3 | Compound 2-19 | ADN | 6.3 | 7.6 | 3,100 |
| | Compound 4-15 | | | | | | |
| Example 5 | Compound 6-2 | Compound 1-3 | Compound 2-3 | ADN | 6.9 | 7.5 | 3,000 |
| | Compound 4-15 | | | | | | |
| Example 6 | Compound 1-3 | Compound 2-3 | Compound 1-3 | ADN | 6.7 | 6.6 | 2,900 |
| | Compound 4-15 | | | | | | |
| Example 7 | Compound 2-3 | Compound 1-3 | Compound 2-3 | ADN | 6.8 | 6.8 | 2,700 |
| | | Compound 4-15 | | | | | |
| Example 8 | Compound 1-3 | Compound 1-3 | Compound 2-25 | ADN | 6.3 | 7.5 | 2,500 |
| | Compound 4-15 | | | | | | |
| Example 9 | Compound 1-3 | Compound 1-3 | Compound 2-31 | ADN | 6.4 | 7.1 | 3,000 |
| | Compound 4-15 | | | | | | |
| Example 10 | Compound 1-3 | Compound 1-3 | Compound 2-3 | ADN | 6.8 | 7.3 | 2,800 |
| | Compound 4-16 | | | | | | |
| Example 11 | Compound 1-3 | Compound 1-3 | Compound 2-3 | DPVBi | 6.5 | 7.4 | 2,900 |
| | Compound 4-15 | | | | | | |
| Example 12 | Compound 1-3 | Compound 1-3 | Compound 2-28 | ADN | 6.3 | 7.0 | 2,200 |
| | Compound 4-15 | | | | | | |
| Example 13 | Compound 1-3 | Compound 1-3 | Compound 2-29 | ADN | 6.4 | 6.9 | 2,500 |
| | Compound 4-15 | | | | | | |
| Example 14 | Compound 1-3 | Compound 1-3 | Compound 2-33 | ADN | 6.5 | 7.3 | 2,800 |
| | Compound 4-15 | | | | | | |
| Comparative | Compound 1-3 | Compound 1-3 | Compound 1-3 | ADN | 6.4 | 7.3 | 2,200 |
| Example 1 | Compound 4-15 | | | | | | |
| Comparative | Compound 1-3 | Compound 1-3 | Compound 6-1 | ADN | 7.6 | 5.5 | 1,900 |
| Example 2 | Compound 4-15 | | | | | | |
| Comparative | Compound 6-2 | Compound 1-3 | Compound 6-1 | ADN | 7.6 | 5.1 | 1,500 |
| Example 3 | | | | | | | |
| Comparative | Compound 1-3 | Compound 1-3 | Compound 2-3 | ADN | 7.6 | 6.0 | 1,700 |
| Example 4 | | | | | | | |
| Comparative | Compound 6-2 | Compound 6-3 | Compound 6-1 | ADN | 8 | 4.5 | 900 |
| Example 5 | | | | | | | |

Organic electroluminescent devices of Examples 2-14 were manufactured in substantially the same manner as in Manufacturing Example 1, except that the following changes were made. In Examples 2 to 4, HTL3 included in the second hole transport layer was as shown in Table 1. In Example 5, the first hole transport material included in the first hole transport layer was changed to be Compound 6-2.

In Example 6, the stacking order of the second hole transport layer and the third hole transport layer was exchanged (for example, the materials included in the third hole transport layer of Example 1 were included in the second hole transport layer of Example 6, and the materials included in the second hole transport layer of Example 1 were included in the third hole transport layer of Example 6). In Example 7, the stacking order of the first hole transport layer and the third hole transport layer was exchanged (for example, the materials included in the first hole transport layer of Example 1 were included in the third hole transport layer of Example 7, and the materials included in the third hole transport layer of Example 1 were included in the first hole transport layer of Example 6). In Examples 8 and 9, HTL3 included in the second hole transport layer was as shown in Table 1. In Example 10, the electron accepting material of Example 1 was changed. In Example 11, the host material of Example 1 was changed. In Examples 12 to 14, HTL3 included in the second hole transport layer was as shown in Table 1.

Organic electroluminescent devices of Comparative Examples 1 and 2 were manufactured in substantially the same manner as in Manufacturing Example 1, except that HTL3 included in the second hole transport layer was as shown in Table 1 (for example, the materials included in the second hole transport layers of Comparative Examples 1 and 2 were Compound 1-3 and Compound 6-1, respectively).

In Comparative Example 3, an organic electroluminescent device was manufactured in substantially the same manner as in Example 5, except that the electron accepting material (Compound 4-15) was not included in the HTL1, and HTL3 changed to Compound 6-1. In Comparative Example 4, an organic electroluminescent device was manufactured in substantially the same manner as in Example 1, except that the electron accepting material (Compound 4-15) was not included in the HTL1. In Comparative Example 5, an organic electroluminescent device was manufactured in substantially the same manner as in Example 5, except that HTL1 to HTL3 included Compounds 6-2, 6-3, and 6-1, respectively.

### Evaluation of Properties of Organic Electroluminescent Device

Driving voltage, emission efficiency and half life of the organic electroluminescent devices according to the Examples and the Comparative Examples were measured. The measurements for the driving voltage and the emission efficiency were obtained using current density of about 10 mA/cm². The measurement for the half life was obtained by measuring the time it took for the initial luminance of about 1,000 cd/m² to reduce by 50%. The measurements were taken using a 2400 series source meter (from Keithley Instruments Co.), Color brightness photometer CS-200 by Konica Minolta holdings, measurement angle of 1°), and a PC program LabVIEW 8.2 (manufactured by National instruments in Japan) for measurements in a dark room. Evaluation results are shown in Table 1.

As illustrated by the results shown in Table 1, the organic electroluminescent devices according to Examples 1 to 14 exhibited better properties of at least one of the emission efficiency and emission life when compared to those of Comparative Examples 1 to 5. In addition, the driving voltage, the emission efficiency and the emission life were better in Example 1 as compared to those of Comparative Examples 1 to 5. Thus, in the organic electroluminescent device of embodiments of the present disclosure, at least one of the emission efficiency and emission life could be increased by providing the first hole transport layer and the second hole transport layer as described herein between the first electrode and the emission layer. In addition, at least one of the emission efficiency and emission life of the organic electroluminescent device could be further improved by providing the second hole transport layer between the first hole transport layer and the emission layer.

As illustrated in Table 1, the properties of Example 1 were the best among Examples 1 to 4. Accordingly, the properties of the organic electroluminescent device can be improved when the second hole transporting material of Formula 2 includes an amine coupled with a dibenzofuran moiety at position 3 of dibenzofuran. In addition, when comparing Example 1 and Example 5, the driving voltage, the emission efficiency and the emission life of Example 1 were better than those of Example 5. Thus, the organic electroluminescent device including the compound represented by Formula 1 the first hole transport material can exhibit improved characteristics. In addition, when comparing Example 1 and Example 6, the driving voltage, the emission efficiency and the emission life of Example 1 were better than those of Example 6. Therefore, the organic electroluminescent device including the second hole transport layer positioned adjacent to (e.g., directly contacting) the emission layer can exhibit improved characteristics.

In addition, when comparing Example 1 and Example 7, the driving voltage, the emission efficiency and the emission life of Example 1 were better than those of Example 7. Therefore, the organic electroluminescent device including the first hole transport layer positioned adjacent to (e.g., directly contacting) the first electrode can exhibit improved characteristics.

In addition, when the first hole transport layer of the organic electroluminescent device included the first hole transport material doped with the electron accepting material according to embodiments of the present disclosure, the driving voltage tended to decrease. Also, when the second hole transport layer of the organic electroluminescent device according to embodiments of the present disclosure was positioned adjacent to (e.g., directly contacting) the emission layer, the emission life tended to increase.

### Manufacturing Example 2 of Organic Electroluminescent Device and Evaluation of Properties Thereof

Organic electroluminescent devices of Examples 16 to 26 and Comparative Examples 6 to 11 having a hole transport layer with a double-layer structure (e.g., as illustrated in FIG. 2) were manufactured by substantially the same procedure as in Manufacturing Example 1 except that HTL2 was not included. The evaluation of the properties of the organic electroluminescent devices was conducted in substantially the same manner as described above. The configuration of each organic electroluminescent device and the results of the evaluation of the properties thereof are summarized and shown in Table 2. As illustrated by the results shown in Table 2, the organic electroluminescent devices exhibited improved properties even though the third hole transport layer including the HTL2 hole transport material was not included.

TABLE 2

| | First Hole | Second Hole | | | | |
|---|---|---|---|---|---|---|
| | Transport Layer | Transport Layer | | | | Half |
| Device | (HTL1 hole | (HTL3 hole | | | Emission | Life |
| manufacturing | transport | transport | Host | Voltage | efficiency | LT50 |
| Example | material) | material) | material | (V) | (cd/A) | (h) |
| Example 15 | Compound 1-3 | Compound 2-3 | ADN | 6.6 | 6.1 | 2,900 |
| | Compound 4-15 | | | | | |
| Example 16 | Compound 1-3 | Compound 2-9 | ADN | 6.6 | 6.5 | 2,100 |
| | Compound 4-15 | | | | | |
| Example 17 | Compound 1-3 | Compound 2-17 | ADN | 6.6 | 7.3 | 2,400 |
| | Compound 4-15 | | | | | |
| Example 18 | Compound 1-3 | Compound 2-19 | ADN | 6.7 | 7.3 | 2,700 |
| | Compound 4-15 | | | | | |
| Example 19 | Compound 6-2 | Compound 2-3 | ADN | 6.9 | 6.9 | 2,700 |
| | Compound 4-15 | | | | | |
| Example 20 | Compound 1-3 | Compound 2-25 | ADN | 7.0 | 7.4 | 2,200 |
| | Compound 4-15 | | | | | |
| Example 21 | Compound 1-3 | Compound 2-31 | ADN | 6.8 | 6.2 | 2,500 |
| | Compound 4-15 | | | | | |
| Example 22 | Compound 1-3 | Compound 2-3 | ADN | 6.8 | 6.7 | 2,800 |
| | Compound 4-15 | | | | | |
| Example 23 | Compound 1-3 | Compound 2-3 | DPVBi | 6.3 | 6.0 | 2,800 |
| | Compound 4-15 | | | | | |
| Example 24 | Compound 1-3 | Compound 2-28 | ADN | 6.3 | 7.1 | 2,200 |
| | Compound 4-15 | | | | | |
| Example 25 | Compound 1-3 | Compound 2-29 | ADN | 6.9 | 6.6 | 2,100 |
| | Compound 4-15 | | | | | |
| Example 26 | Compound 1-3 | Compound 2-33 | ADN | 6.3 | 7.3 | 2,500 |
| | Compound 4-15 | | | | | |
| Comparative | Compound 1-3 | Compound 1-3 | ADN | 6.5 | 7.0 | 2,000 |
| Example 6 | Compound 4-15 | | | | | |
| Comparative | Compound 1-3 | Compound 6-1 | ADN | 7.6 | 5.2 | 1,700 |
| Example 7 | Compound 4-15 | | | | | |
| Comparative | Compound 6-2 | Compound 6-1 | ADN | 7.6 | 5.1 | 1,600 |
| Example 8 | | | | | | |
| Comparative | Compound 1-3 | Compound 2-3 | ADN | 7.3 | 5.8 | 1,700 |
| Example 9 | | | | | | |
| Comparative | Compound 6-2 | Compound 6-1 | ADN | 7.8 | 4.8 | 800 |
| Example 10 | | | | | | |
| Comparative | Compound 2-3 | Compound 1-3 | ADN | 8.3 | 4.0 | 1,200 |
| Example 11 | | Compound 4-15 | | | | |

According to the above example embodiments, when the second hole transport layer was provided between the first hole transport layer and the emission layer, the emission efficiency and emission life of the organic electroluminescent device were improved. For example, the organic electroluminescent device of embodiments of the present disclosure may be able to effectively perform functions including (1) passivating the hole transport layer from electrons not consumed in the emission layer, (2) preventing or reducing the diffusion of energy of an excited state generated (e.g., excitons) from the emission layer to the hole transport layer, and (3) controlling the charge balance of the entire organic electroluminescent device. Without being bound by any particular theory, it is believed that the above-mentioned improved properties of the organic electroluminescent device may be obtained because the second hole transport layer may restrain or reduce the diffusion of the electron accepting material positioned adjacent to (e.g., directly contacting) the first electrode into the emission layer.

In some embodiments, the silyl group in the second hole transport material of Formula 2 may be substituted with a substituted or unsubstituted aryl group, and in this case, at least one of the emission efficiency and emission life of the organic electroluminescent device may be improved further.

In some embodiments, the silyl group in the second hole transport material of Formula 2 may be substituted with an unsubstituted phenyl group, and in this case, at least one of the emission efficiency and emission life of the organic electroluminescent device may be improved further.

In some embodiments, in the second hole transport material of Formula 2, L may be combined (or coupled) with a dibenzofuranyl group at position 3, and in this case, at least one of the emission efficiency and emission life of the organic electroluminescent device may be improved further.

In some embodiments, the first hole transport material may have a structure represented by Formula 1, and in this case, at least one of the emission efficiency and emission life of the organic electroluminescent device may be improved further.

In some embodiments, the electron accepting material doped into the first hole transport layer may have a LUMO level from about −9.0 to about −4.0 eV, and in this case, at least one of the emission efficiency and emission life of the organic electroluminescent device may be improved further.

In some embodiments, the emission layer may include the luminescent material having a structure represented by Formula 3, and in this case, at least one of the emission efficiency and emission life of the organic electroluminescent device may be improved further.

In some embodiments, the second hole transport layer may be between the first hole transport layer and the emission layer, and in this case, at least one of the emission efficiency and emission life of the organic electroluminescent device may be improved further.

In some embodiments, the second hole transport layer may be adjacent to (e.g., directly contacting) the emission layer, and in this case, at least one of the emission efficiency and emission life of the organic electroluminescent device may be improved further.

In some embodiments, the first hole transport layer may be adjacent to (e.g., directly contacting) an anode (or the first electrode), and in this case, at least one of the emission efficiency and emission life of the organic electroluminescent device may be improved further.

In some embodiments, the third hole transport layer may be provided between the first hole transport layer and the second hole transport layer, and in this case, at least one of the emission efficiency and emission life of the organic electroluminescent device may be improved further.

The above-disclosed subject matter is to be considered illustrative and not restrictive, and the appended claims and equivalents thereof are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Expressions such as “at least one selected from” and “one selected from,” when preceding a list of elements, modify the entire list of elements and do not modify the individual elements of the list. Further, the use of “may” when describing embodiments of the present disclosure refers to “one or more embodiments of the present disclosure.”

In addition, as used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent deviations in measured or calculated values that would be recognized by those of ordinary skill in the art.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. §112a, and 35 U.S.C. §132(a).

What is claimed is:

1. An organic electroluminescent device, comprising:
an anode;
an emission layer;
a first hole transport layer between the anode and the emission layer, the first hole transport layer comprising a first hole transport material and an electron accepting material doped into the first hole transport material; and
a second hole transport layer between the anode and the emission layer, the second hole transport layer comprising a second hole transport material represented by Formula 2: 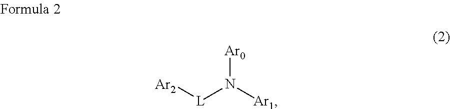
wherein, in Formula 2, Ar₀ to A₁ are each independently selected from a substituted or unsubstituted aryl group and a substituted or unsubstituted heteroaryl group,
at least one selected from Ar₀ and Ar₁ is substituted with a substituted or unsubstituted silyl group,
Ar₂ is a substituted or unsubstituted dibenzofuranyl group, and
L is selected from a direct linkage, a substituted or unsubstituted arylene group, and a substituted or unsubstituted heteroarylene group.

2. The organic electroluminescent device of claim 1, wherein the substituted silyl group is substituted with a substituted or unsubstituted aryl group.

3. The organic electroluminescent device of claim 2, wherein the substituted silyl group is substituted with an unsubstituted phenyl group.

4. The organic electroluminescent device of claim 1, wherein L is coupled to Ar₂ at position three (3) of the dibenzofuranyl group.

5. The organic electroluminescent device of claim 1, wherein the first hole transport material is represented by Formula 1: 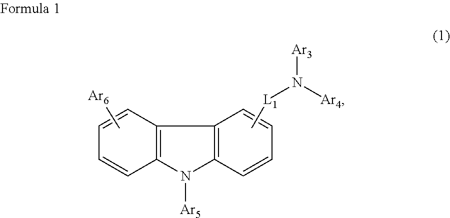
wherein, in Formula 1,
Ar₃ to Ar₅ are each independently selected from a substituted or unsubstituted aryl group and a substituted or unsubstituted heteroaryl group,
Ar₆ is selected from a substituted or unsubstituted aryl group, a substituted or unsubstituted heteroaryl group, a carbazolyl group, and an alkyl group, and
L₁ is selected from a direct linkage, a substituted or unsubstituted arylene group, and a substituted or unsubstituted heteroarylene group.

6. The organic electroluminescent device of claim 1, wherein the electron accepting material has the lowest unoccupied molecular orbital (LUMO) level from about −9.0 eV to about −4.0 eV.

7. The organic electroluminescent device of claim 1, wherein the emission layer comprises a luminescent material represented by Formula 3: 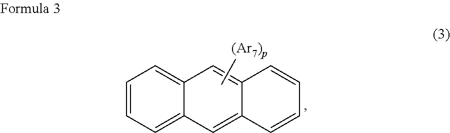
wherein, in Formula 3,
Ar₇ is selected from a hydrogen atom, a deuterium atom, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group, and a hydroxyl group, and
p is an integer from 1 to 10.

8. The organic electroluminescent device of claim 1, wherein the second hole transport layer is between the first hole transport layer and the emission layer.

9. The organic electroluminescent device of claim 8, wherein the second hole transport layer is adjacent to the emission layer.

10. The organic electroluminescent device of claim 1, wherein the first hole transport layer is adjacent to the anode.

11. The organic electroluminescent device of claim 1, further comprising a third hole transport layer between the first hole transport layer and the second hole transport layer, the third hole transport layer comprising at least one selected from the first hole transport material and the second hole transport material.

12. The organic electroluminescent device of claim 1, wherein the first hole transport material comprises at least one compound represented by any of Formulae 1-1 to 1-16:

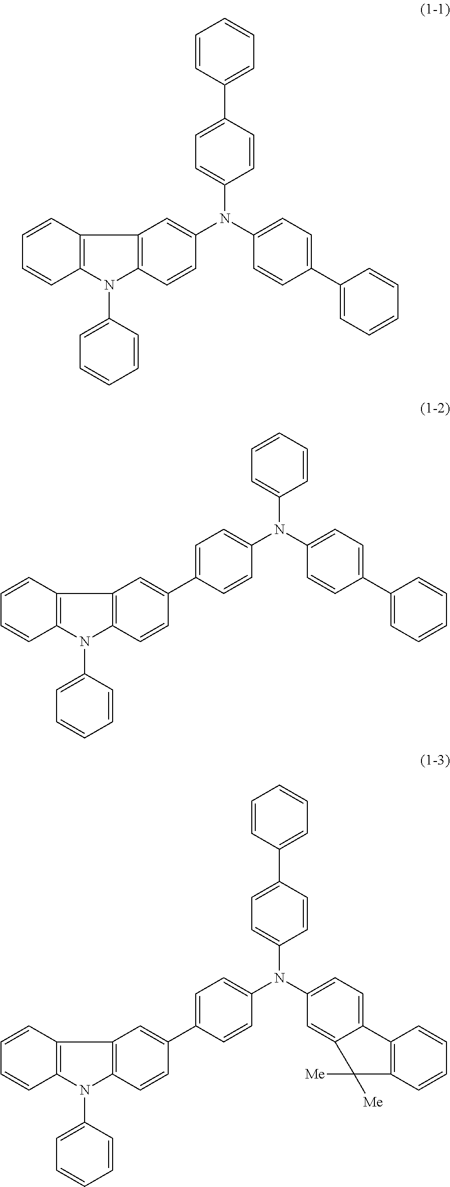 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

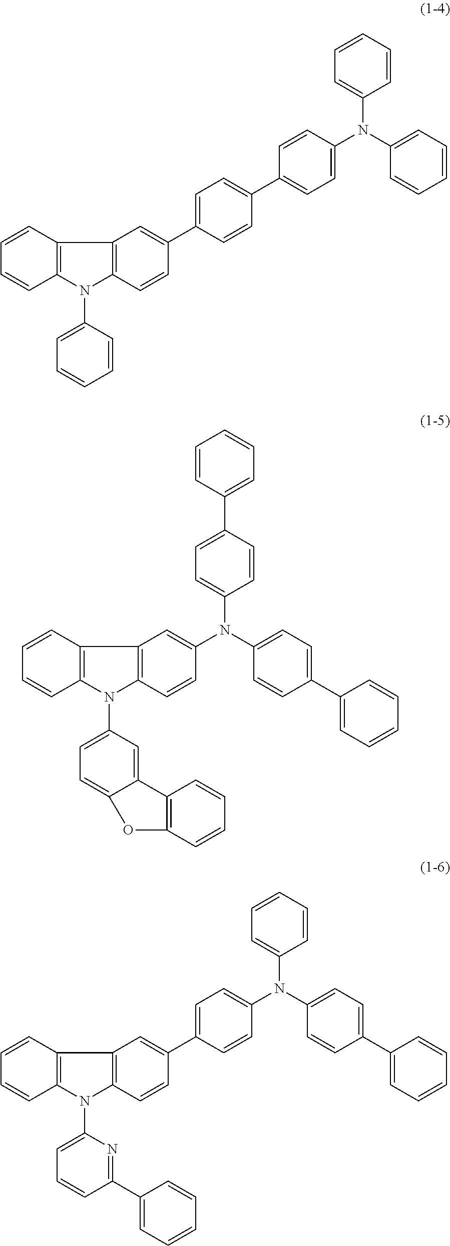 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

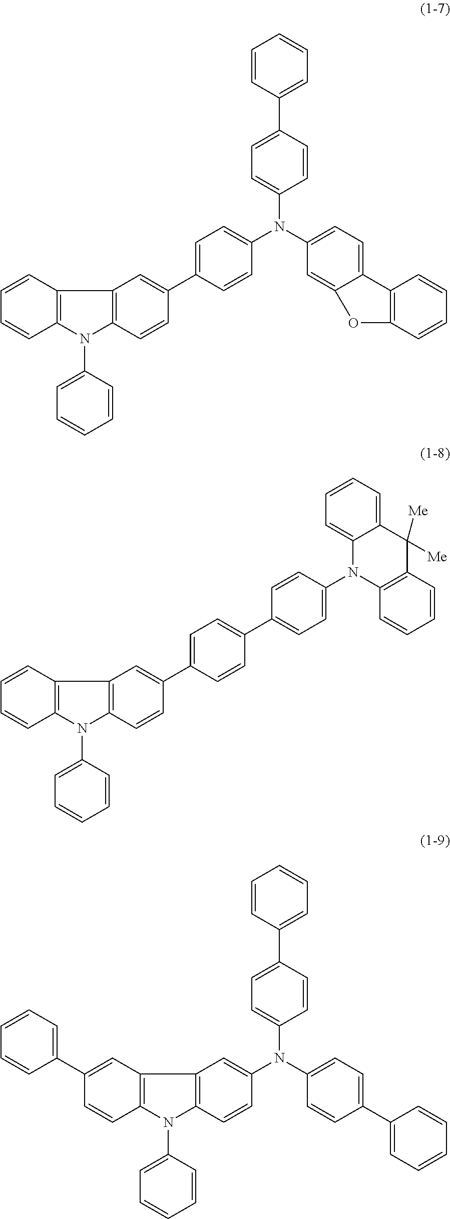 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

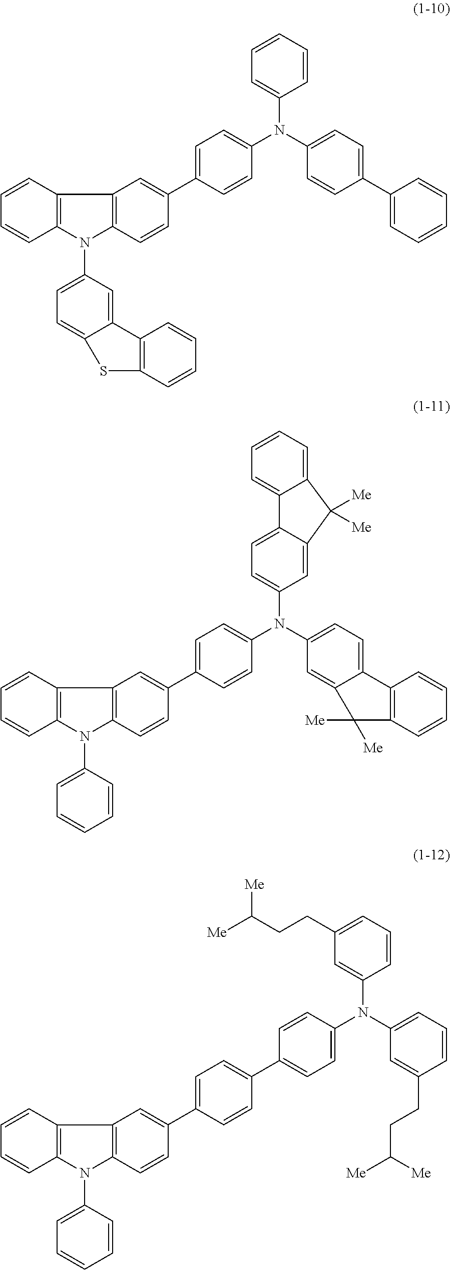 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

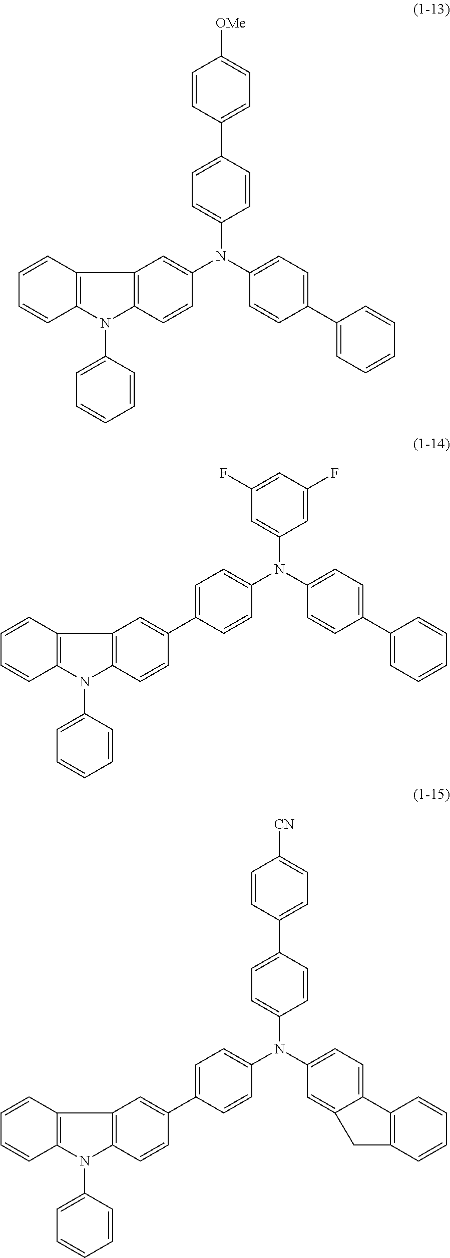 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

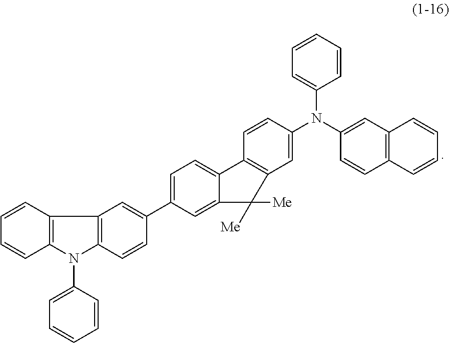 [SMILES: CC1(C)c2cc(-c3ccc4c(c3)c3ccccc3n4-c3ccccc3)ccc2-c2ccc(N(c3ccccc3)c3ccc4ccccc4c3)cc21]

13. The organic electroluminescent device of claim 1, wherein the second hole transport material comprises at least one compound represented by any of Formulae 2-1 to 2-34:

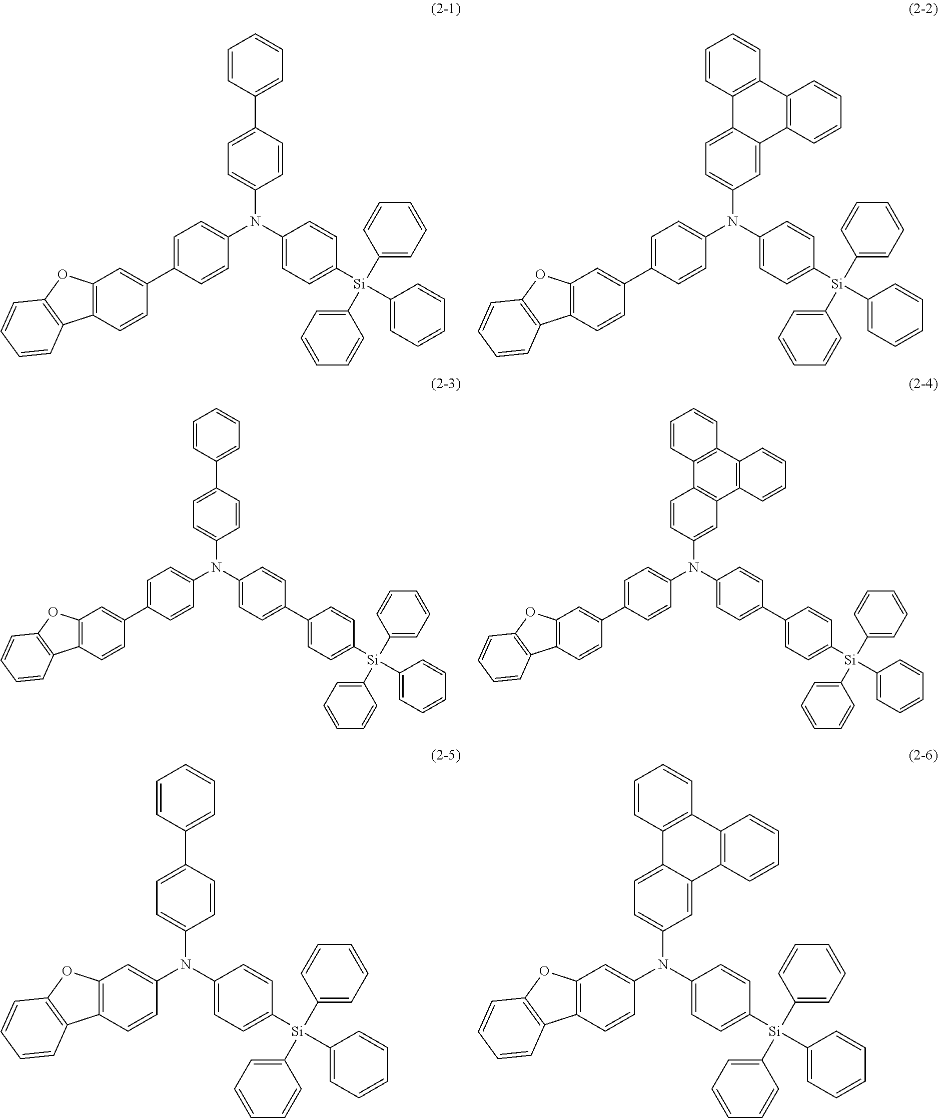

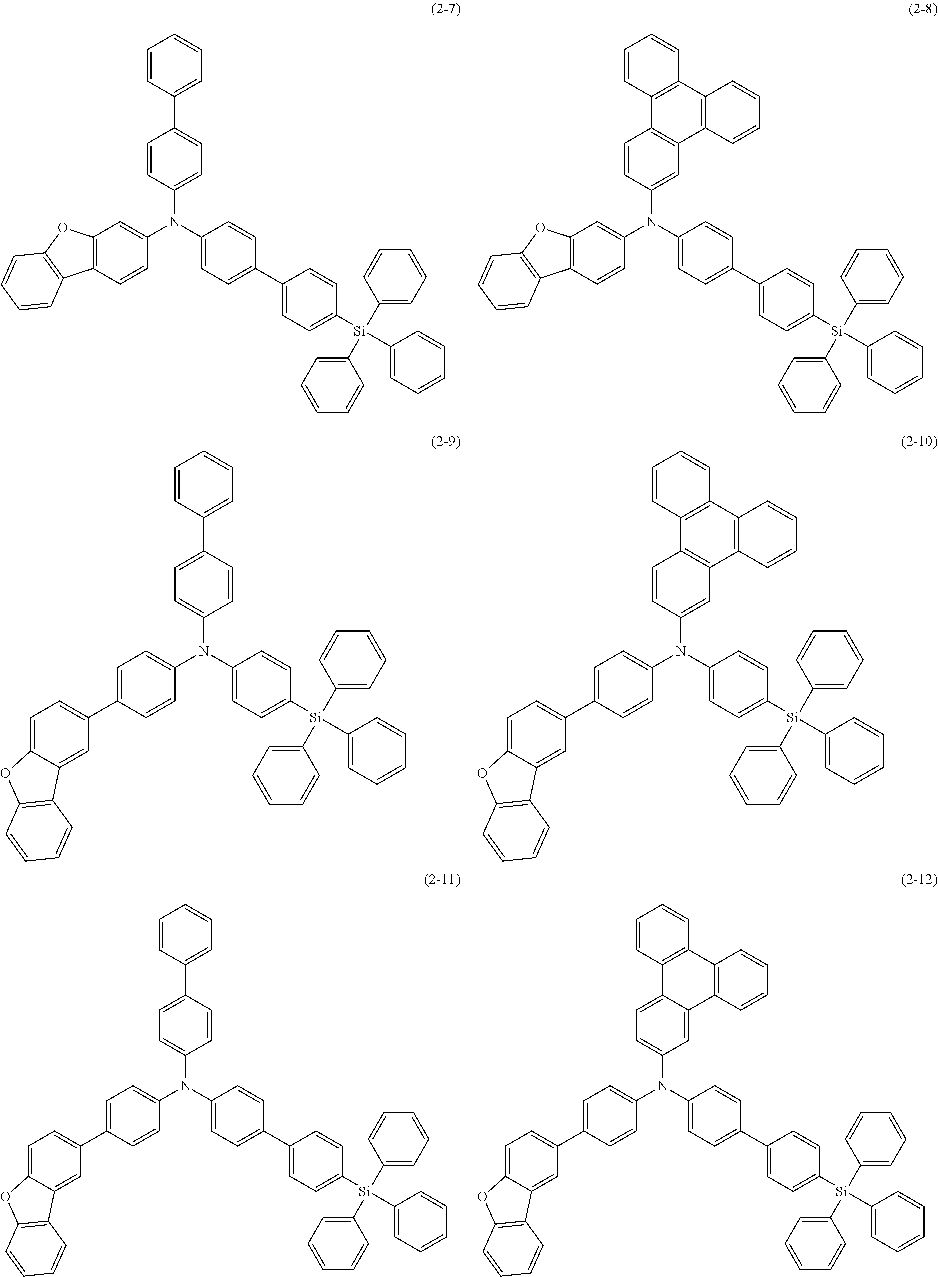

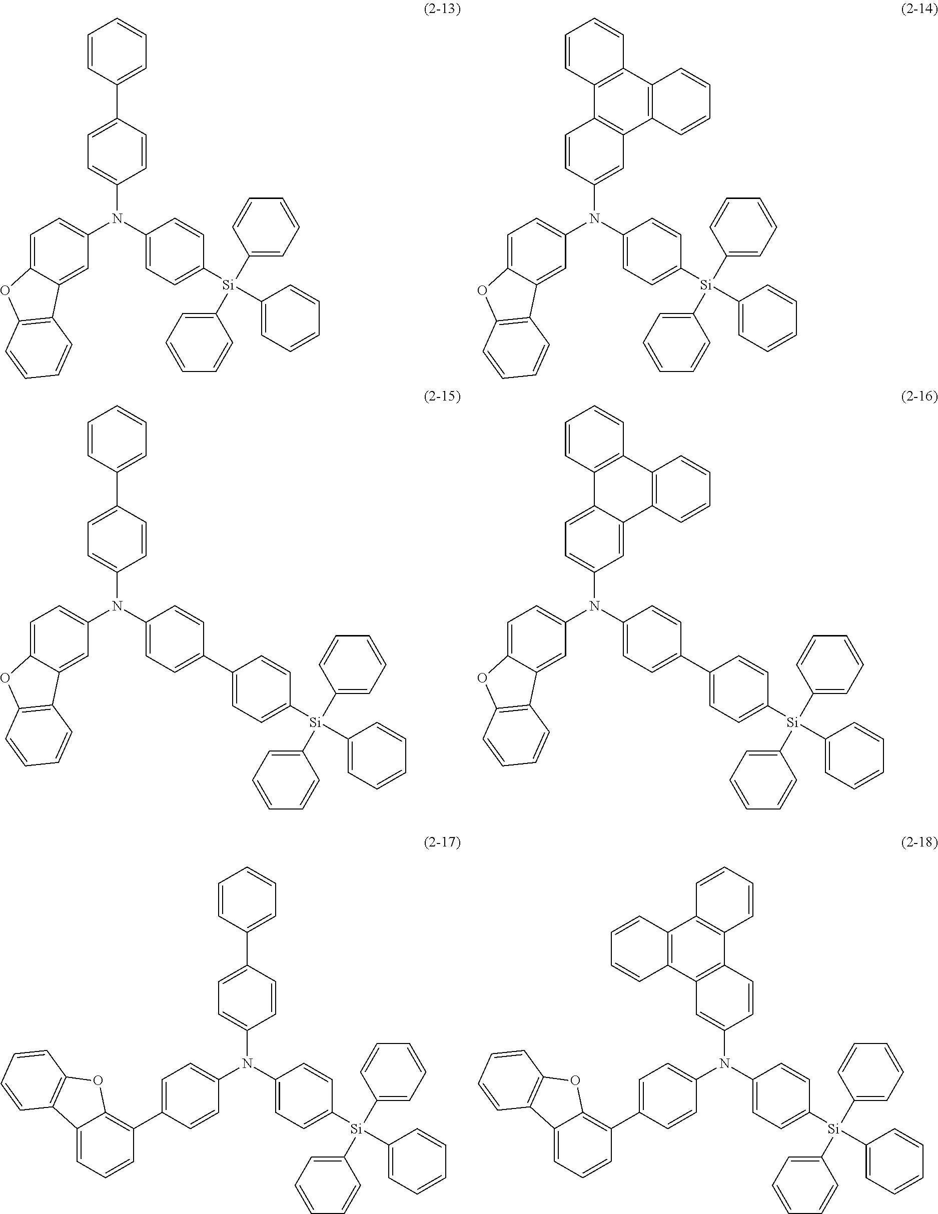

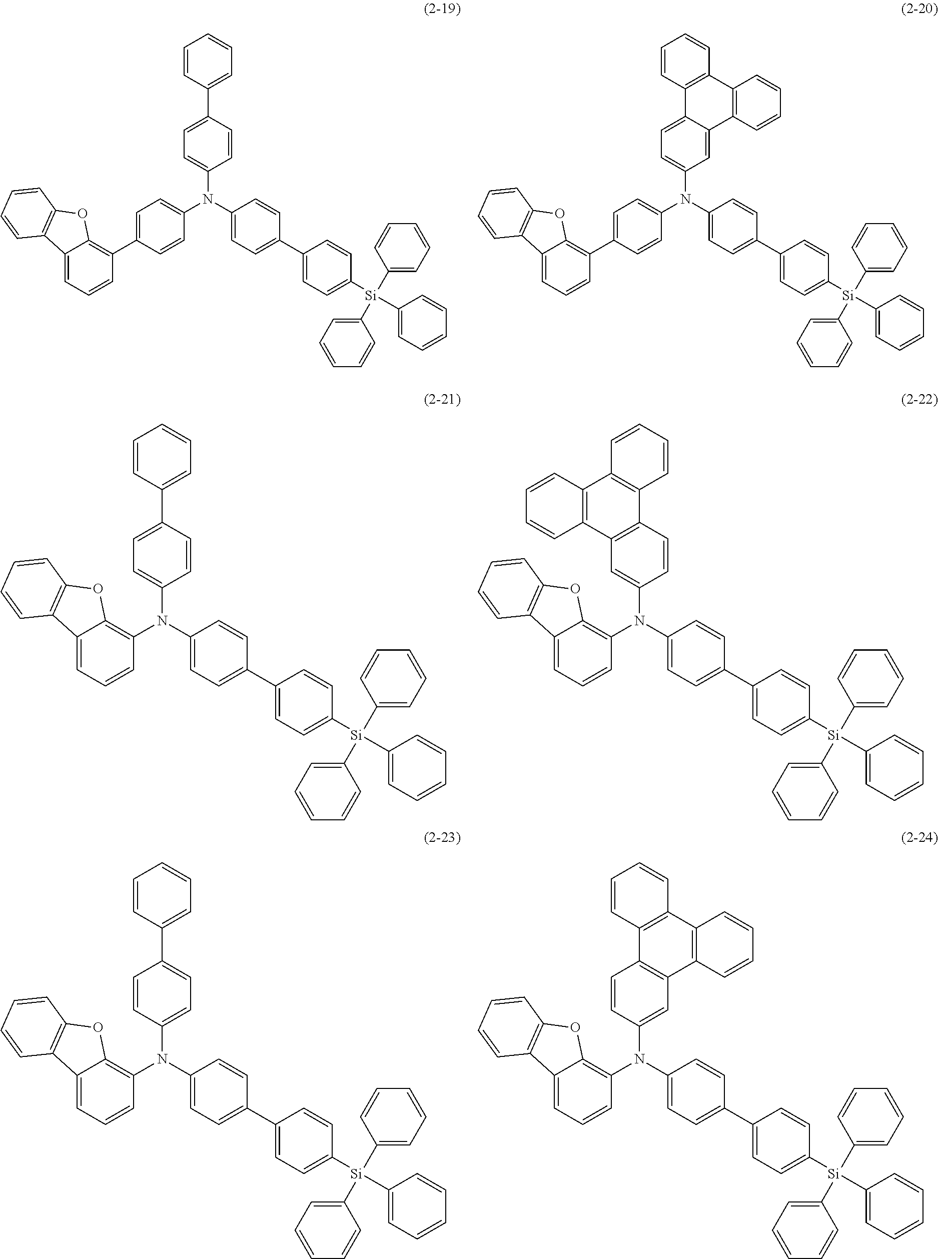

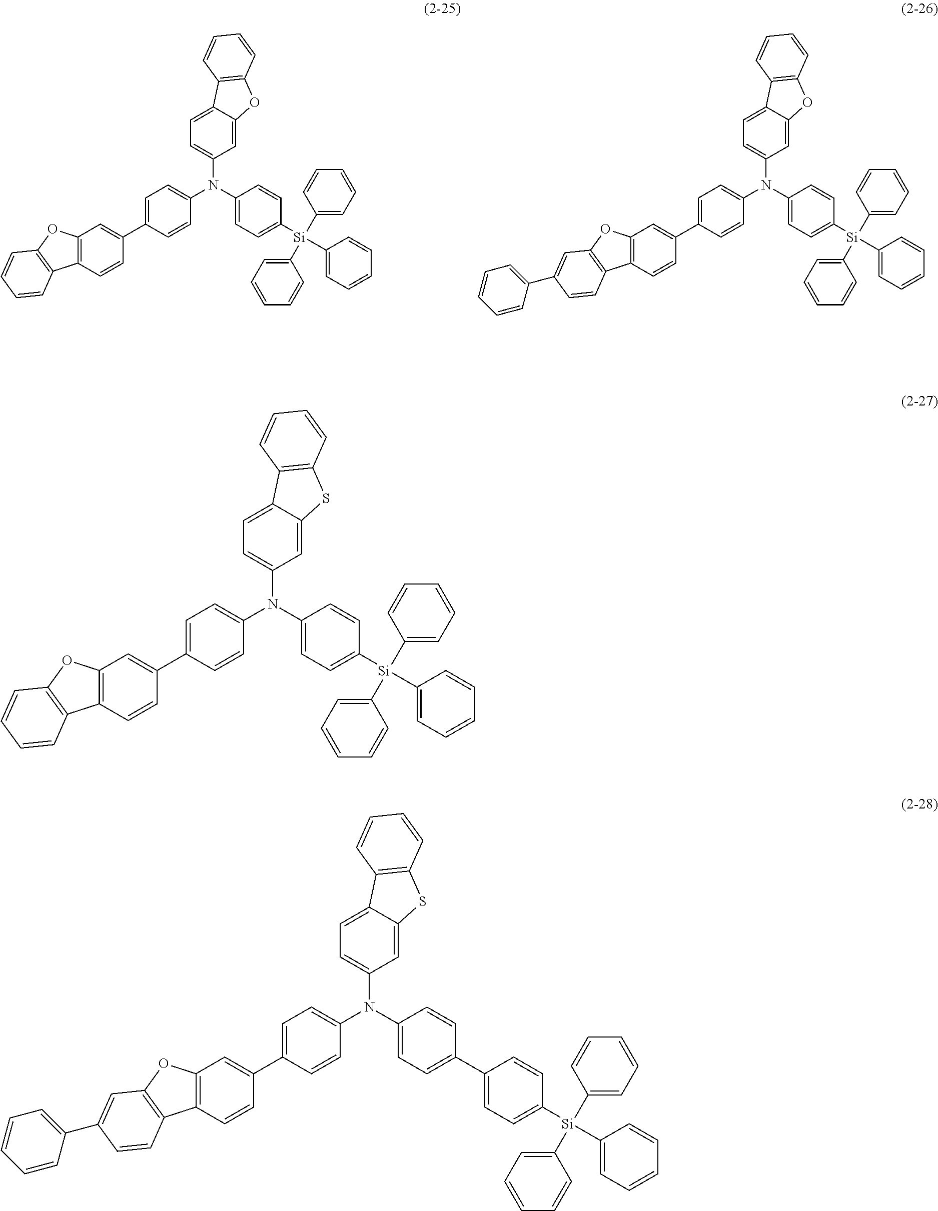 [SMILES: c1ccc([Si](c2ccccc2)(c2ccccc2)c2ccc(N(c3ccc(-c4ccc5c(c4)oc4ccccc45)cc3)c3ccc4c(c3)oc3ccccc34)cc2)cc1 ; c1ccc(-c2ccc3c(c2)oc2cc(-c4ccc(N(c5ccc([Si](c6ccccc6)(c6ccccc6)c6ccccc6)cc5)c5ccc6c(c5)oc5ccccc56)cc4)ccc23)cc1 ; c1ccc([Si](c2ccccc2)(c2ccccc2)c2ccc(N(c3ccc(-c4ccc5c(c4)oc4ccccc45)cc3)c3ccc4c(c3)sc3ccccc34)cc2)cc1 ; c1ccc(-c2ccc3c(c2)oc2cc(-c4ccc(N(c5ccc(-c6ccc([Si](c7ccccc7)(c7ccccc7)c7ccccc7)cc6)cc5)c5ccc6c(c5)sc5ccccc56)cc4)ccc23)cc1]

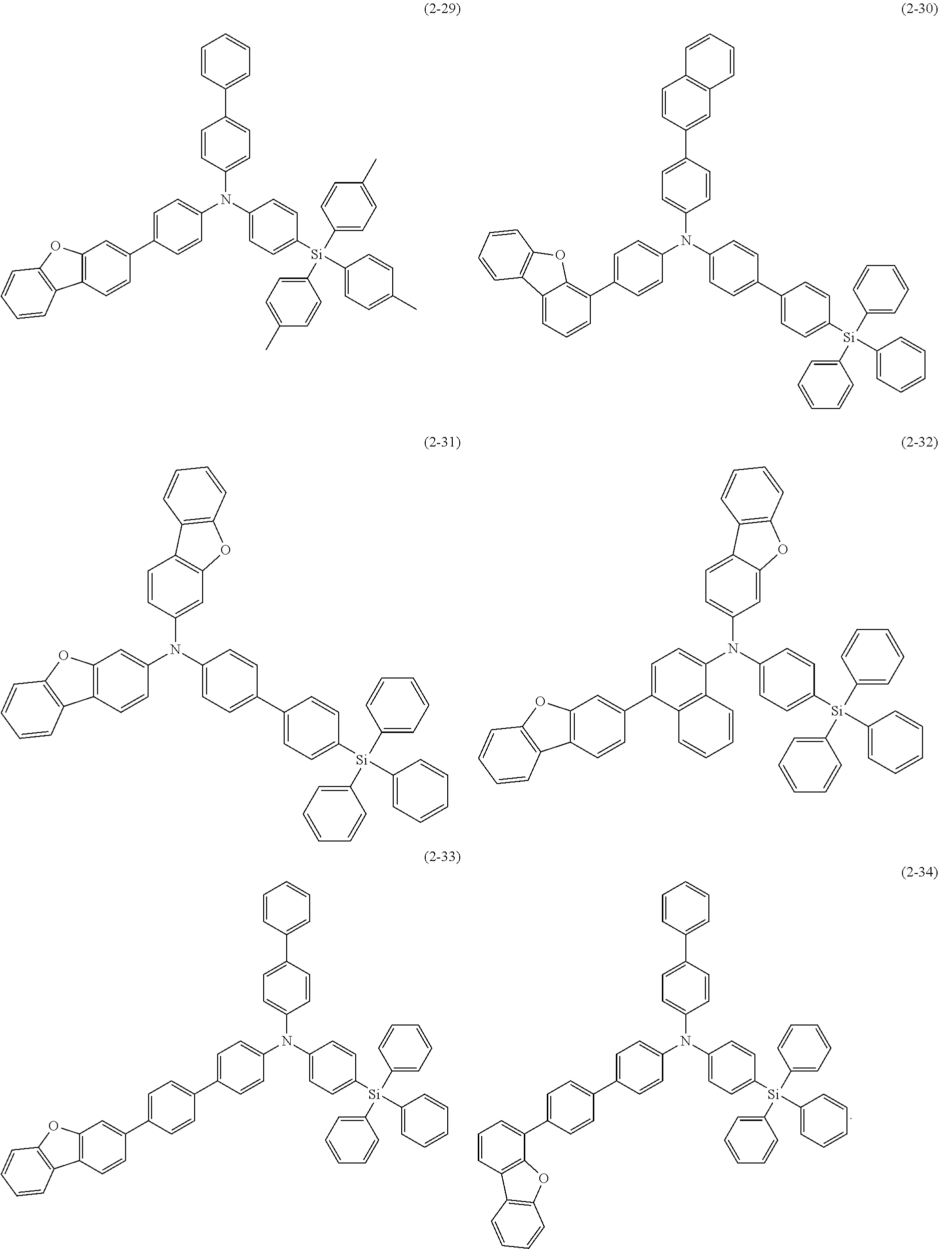

14. The organic electroluminescent device of claim 1, wherein the emission layer comprises at least one compound represented by any of Formulae 3-1 to 3-12: 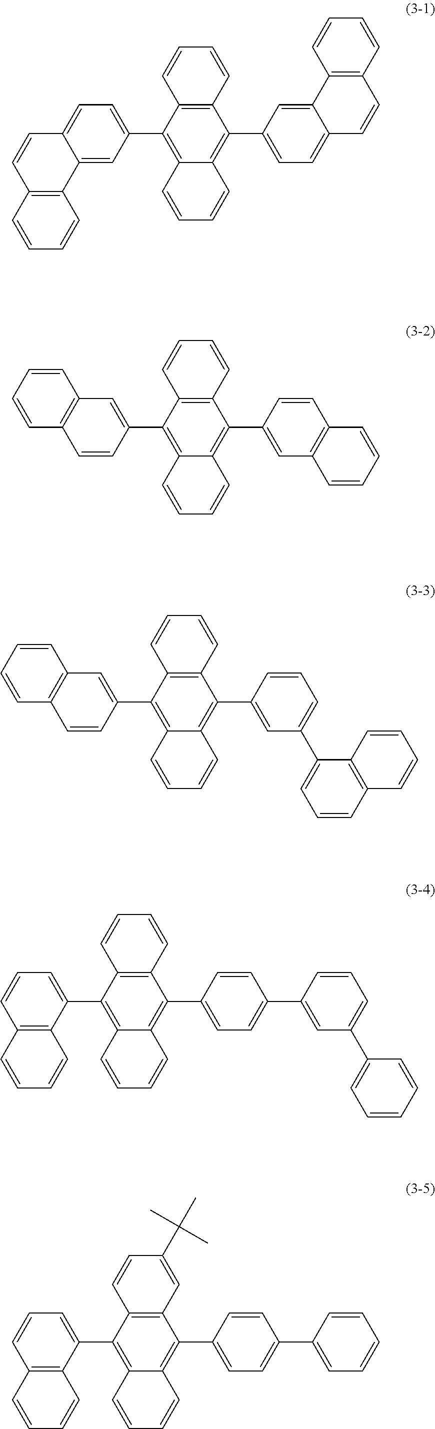 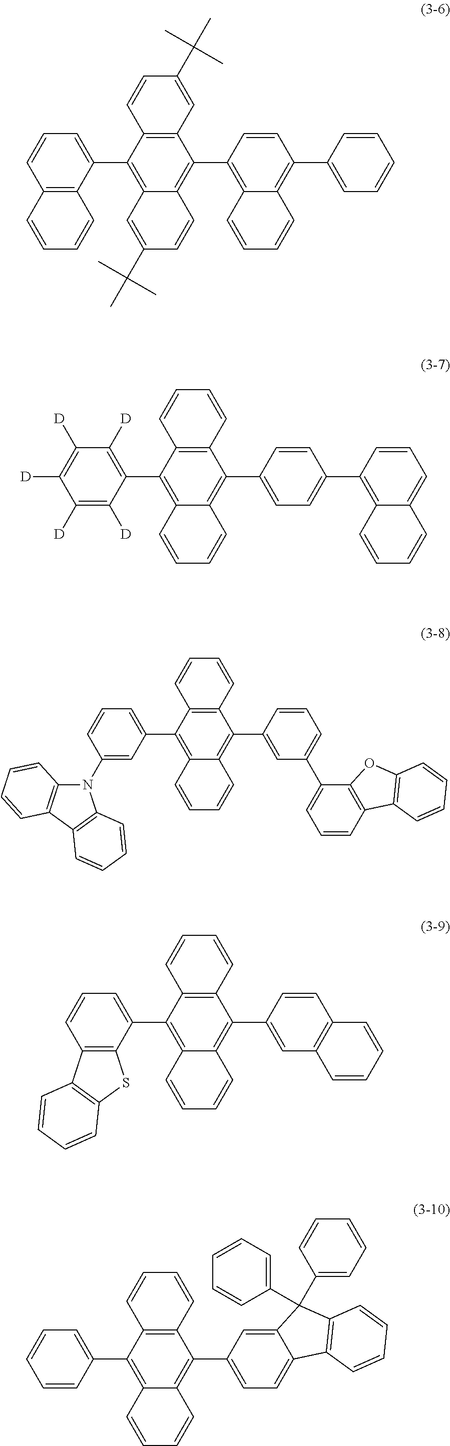 [chemical structure]
